(19) United States
(12) Patent Application Publication
(10) Pub. No.: US 2018/0294617 A1
(43) Pub. Date: Oct. 11, 2018

(54) GAMMA-RAY ELECTRON BEAM TRANSDUCER

(71) Applicant: Randell L. MILLS, Coatesville, PA (US)

(72) Inventor: Randell L. MILLS, Coatesville, PA (US)

(21) Appl. No.: 15/765,942

(22) PCT Filed: Oct. 5, 2016
(86) PCT No.: PCT/US2016/055545

§ 371 Date: Apr. 4, 2018

Related U.S. Application Data
(60) Provisional application No. 62/237,294, filed on Oct. 5, 2015.
(60) Provisional application No. 62/374,663, filed on Aug. 12, 2016.
(60) Provisional application No. 62/382,386, filed on Sep. 1, 2016.

(51) Int. Cl. H01S 3/09; F03G 3/08; H05H 7/04; G03F 7/20; H05G 2/00

(52) U.S. Cl. CPC H01S 3/0903; F03G 3/08; H05G 2/00; G03F 7/70025; H05H 7/04

(57) ABSTRACT

A method and means to produce a propulsion force comprises a source of electrons and means to produce pseudoelectrons. A gravitating body such as the Earth provides a repulsive fifth force on the pseudoelectrons. Pseudoelectrons are produced by absorption of high-energy photons by electrons. The pseudoelectrons experience a fifth force (F²) away from the Earth and move upward away from the Earth. To use this F² device for propulsion, the repulsive fifth force on the pseudoelectrons is transferred to a negatively charged plate. The Coulombic repulsion between the pseudoelectrons and the negatively charged plate causes the plate to lift. The craft may additionally be imparted with angular momentum along an axis defined by the gravitational force, and the craft may be tilted to move the vector away from the axis where a component of acceleration tangential to a surface of a gravitating body is achieved via conservation of angular momentum.

### RELATED APPLICATIONS

This International Patent Application claims priority to U.S. Ser. No. 62/237,294 filed Oct. 5, 2015, U.S. Ser. No. 62/374,663 filed Aug. 12, 2016, and U.S. Ser. No. 62/382,386 filed Sep. 1, 2016, the contents of which are incorporated by reference.

### BACKGROUND

### 1. Field

This disclosure relates to methods and apparatus for providing propulsion, in particular methods and apparatus for providing propulsion using absorption of X-ray or gamma ray photons by free electro

### 2. Description of the Related Art

The attractive gravitational force has been the subject of investigation for centuries. Traditionally, gravitational attraction has been investigated in the field of astrophysics applying a large-scale perspective of cosmological spacetime, as ns. distinguished from currently held theories of atomic and subatomic structure. However, gravity originates on the atomic scale. In Newtonian gravitation, the mutual attraction between two particles of masses m₁ and m₂ separated by a distance r is

$$F = G \frac{{m}_{1} {m}_{2}}{{r}^{2}} \qquad ( 1 )$$

where G is the gravitational constant, its value being 6.67×10⁻¹¹ Nm²k_{g}⁻² . Although Newton's theory gives a correct quantitative description of the gravitational force, the most elementary feature of gravitation is still not well defined. What is the most important feature of gravitation in terms of fundamental principles? By comparing Newton's second law,

F=ma (2)

with his law of gravitation, we can describe the motion of a freely falling object by using the following equation:

$${m}_{i} a = {m}_{g} \frac{{GM}_{⊕}}{{r}^{3}} r \qquad ( 3 )$$

where mᵢ and m_{g} represent respectively the object's inertial mass (inversely proportional to acceleration) and the gravitational mass (directly proportional to gravitational force), M_{⊕} is the gravitational mass of the Earth, and r is the position vector of the object taken from the center of the Earth. The above equation can be rewritten as

$$a = \frac{{m}_{g}}{{m}_{i}} ( \frac{{GM}_{⊕}}{{r}^{2}} ) \qquad ( 4 )$$

Extensive experimentation dating from Galileo's Pisa experiment to the present has shown that irrespective of the object chosen, the acceleration of an object produced by the gravitational force is the same, which from Eq. (4) implies that the value of m_{g}/mᵢ should be the same for all objects. In other words, we have

$$\frac{{m}_{g}}{{m}_{i}} = universal constant \qquad ( 5 )$$

the equivalence of the gravitational mass and the inertial mass, the fractional deviation of Eq. (5) from a constant, is experimentally confirmed to less 1×10⁻¹¹. In physics, the discovery of a universal constant often leads to the development of an entirely new theory. From the universal constancy of the velocity of light c, the special theory of relativity was derived; and from Planck's constant h, the quantum theory was deduced. Therefore, the universal constant m_{g}/mᵢ should be the key to the gravitational problem. The theoretical difficulty with Newtonian gravitation is to explain just why relation, Eq. (5), exists implicitly in Newton's theory as a separate law of nature besides Eqs. (1) and (2). Furthermore, discrepancies between certain astronomical observations and predictions based on Newtonian celestial mechanics exist, and they apparently could not be reconciled until the development of Einstein's theory of general relativity which can be transformed to Newtonian gravitation on the scale in which Newton's theory holds.

Einstein's general relativity is the geometric theory of gravitation developed by Albert Einstein, whereby he intended to incorporate and extend the special theory of relativity to accelerated frames of reference. Einstein's theory of general relativity is based on a flawed dynamic formulation of Galileo's law. Einstein took as the basis to postulate his gravitational field equations a certain kinematical consequence of a law that he called the “Principle of Equivalence” which states that it is impossible to distinguish a uniform gravitational field from an accelerated frame. However, the two are not equivalent since they obviously depend on the direction of acceleration relative to the gravitation body and the distance from the gravitating body since the gravitational force is a central force. (In the latter case, only a line of a massive body may be exactly radial, not the entire mass.) And, this assumption leads to conflicts with special relativity. The success of Einstein's gravity equation can be traced to a successful solution which arises from assumptions and approximations whereby the form of the solution ultimately conflicts with the properties of the original equation, no solution is consistent with the experimental data in the case of the possible cosmological solutions of Einstein's general relativity. All cosmological solutions of general relativity predict a decelerating universe from a postulated initial condition of a “Big Bang” expansion. The astrophysical data reveals an accelerating cosmos that invalidates Einstein's equation. It has been shown that the correct basis of gravitation is not according to Einstein's equation; instead the origin of gravity is the relativistic correction of spacetime itself which is analogous to the special relativistic corrections of inertial parameters—increase in mass, dilation in time, and contraction in length in the direction of constant relative motion of separate inertial frames. On this basis, the observed acceleration of the cosmos is predicted as given in the Gravity Section of Mills GUTCP. Furthermore, Einstein's general relativity is a partial theory in that it deals with matter on a cosmological scale, but not an atomic scale. All gravitating bodies are composed of matter and are collections of atoms that are composed of fundamental particles such as electrons, which are leptons, and quarks that make up protons and neutrons. Gravity originates from the fundamental particles.

As a result of the erroneous assumptions and incomplete or erroneous models and theories, the development of useful or functional systems and structures requiring an accurate understanding of atomic structure and the nature of gravity on the atomic scale have been inhibited. On a scale of gravitating bodies, the Theory of General Relativity is correct experimentally; however, it is incompatible with observation of an acceleration expansion on a cosmological scale, and is incompatible with the current atomic theory of quantum mechanics. And, the Schrodinger equation upon which quantum mechanics is based does not explain the phenomenon of gravity and, in fact, predicts infinite gravitational fields in empty vacuum. Thus, advances in development of propulsion systems which function according to gravitational forces on the atomic scale are prohibited.

### SUMMARY OF THE INVENTION

While the inventive methods and apparatus described in detail further below may be practiced as described, the following discussion of a novel theoretical basis is provided for additional understanding. The background classical physics for support is disclosed in R. Mills, The Grand Unified Theory of Classical Physics, Sep. 3, 2016 Edition, available from Brilliant Light Power, Inc., Cranbury, N.J., and on line www.brilliantlightpower.com which is incorporated herein by this reference. The Schwarzschild metric gives the relationship whereby matter causes relativistic corrections to spacetime that determines the curvature of spacetime and is the origin of gravity. The correction is based on the boundary conditions that no signal can travel faster that the speed of light including the gravitational field that propagates following particle production from a photon wherein the particle has a finite gravitational velocity given by Newton's Law of Gravitation. It is possible to give the electron a spatial negative curvature and, therefore, cause the electron to have a positive inertial mass but a negative gravitational mass. An engineered spacecraft is disclosed.

A propulsion device called a fifth force or F² device comprises a source of matter, a means to give the matter spatial negative curvature which causes the matter to react to a gravitation body such that it has a negative gravitational mass, and a means to produce a force on the matter in opposition to the repulsive gravitational force between the matter and the gravitating body. The force on the matter is applied in the opposite direction of the force of the gravitating body on the matter. One or more of an electric field, a magnetic field, or an electromagnetic field provide this second force. The repulsive force of the gravitating body is then transferred to the source of the second force that further transfers the force to an attached structure to be propelled. In response to the applied force, the matter produces useful work against the gravitational field of the gravitating body.

In one embodiment the propulsion means comprises a source of electrons that serve as the matter. It is possible irradiate the electrons with high intensity short wavelength light such as X-ray or gamma ray light such that electrons absorb the photons to form spatial current and charge state having negative curvature (pseudoelectrons). The pseudoelectrons experience a force away from a gravitating body (e.g. the Earth), and they will tend to move upward (away from the Earth). To use this F² device for propulsion, the upward force of the pseudoelectrons is transferred to a negatively charged plate. The Coulombic repulsion between the pseudoelectrons and the negatively charged plate causes the plate (and anything connected to the plate) to lift.

The equations and/or figures with a prefix number (i.e. of the form #.#) and sections other than those disclosed herein refer to those of Mills GUTCP [R. Mills, The Grand Unified Theory of Classical Physics, Sep.3, 2016 Edition, posted at http://www.blacklightpower.com/theory/bookdownload.shtml] which is herein incorporated by reference in its entirety.

### BRIEF DESCRIPTION OF THE FIGURES

These and further features of the present disclosure will be better understood by reading the following sections taken together with the drawings, wherein:

FIG. 1 is a schematic representation of the curvature of a surface having a generally saddle-type shape.

FIG. 2 is a schematic representation of the curvature of a surface having a generally hyperboloid shape.

FIG. 3 is a schematic representation of the curvature of a surface having a generally conical shape.

FIG. 4 is a schematic representation of the curvature of a surface having a generally pseudospherical shape.

FIG. 5 depicts the half-space surface rendering of a constant Gaussian curvature K=−1, where the complete surface comprises additionally the mirror image.

FIG. 6 depicts a pseudosphere showing rulings of the tractrix along the asymptote axis.

FIG. 7 is a representation of a pseudoelectron.

FIG. 8 depicts a representation of the standard unit normal vector field of the electric field of a pseudoelectron.

FIG. 9A is a schematic representation of a fifth force device comprising a free electron laser (FEL) gamma ray source to produce pseudoelectrons in a fifth force generator and transfer the force to an attached movable object.

FIG. 9B is a cross sectional view of a fifth force device comprising a Bremsstrahlung gamma ray source to produce pseudoelectrons.

FIG. 9C is a cross sectional view of a fifth force device comprising an inverse Compton scattering (ICS) device gamma ray source to produce pseudoelectrons.

FIG. 9D is a cross sectional view of a fifth force generator.

FIG. 10 is a schematic representation of the forces on a spinning craft that is caused to tilt.

FIG. 11A is a schematic representation of a fifth-force apparatus according to one embodiment to produce pseudoelectrons and transfer a fifth-force to an attached structure.

FIG. 11B is a schematic representation of the fifth-force apparatus further comprising a free electron laser source of at least one of photons and electrons.

FIG. 11C is a schematic representation of the fifth-force apparatus comprising an in-line photon source.

FIG. 11D is a schematic representation of the fifth-force apparatus further comprising a free electron laser source of at least one of photons and electrons with an in-line photon source.

FIG. 11E is a schematic representation of the fifth-force apparatus showing no photon source wherein the interaction of the high-energy electron beam with matter in the guide creates the high-energy photons.

FIG. 11F is a schematic representation of the fifth-force apparatus with a free electron laser replacing the photon source as a source of at least one of photons and electrons.

### DETAILED DESCRIPTION

The physical basis of the equivalence of inertial and gravitational mass of fundamental particles is given in the Equivalence of Inertial and Gravitational Masses Due to Absolute Space and Absolute Light Velocity section wherein spacetime is Riemannian due to a relativistic correction to spacetime with particle production. The Schwarzschild metric gives the relationship whereby matter causes relativistic corrections to spacetime that determines the curvature of spacetime and is the origin of gravity. Matter arises during particle production from a photon and comprises mass and charge confined to a two dimensional surface. Matter of fundamental particles such as an electron has zero thickness. But, in order that the speed of light is a constant maximum in any frame including that of the gravitational field that propagates out as a light-wave front at particle production, the production event gives rise to a spacetime dilation equal to 2π times the Newtonian gravitational or Schwarzschild radius

$${r}_{g} = \frac{2 {Gm}_{e}}{{c}^{2}} = 1.3525 \times {10}^{- 57} m$$

of the particle according to Eqs. (32.36) and (32.140b) and the discussion at the footnote after Eq. (32.40). For the electron, this corresponds to a spacetime dilation of 8.4980×10⁻⁵⁷ m or 2.8346×10⁻⁶⁵ s . Although the electron does not occupy space in the third spatial dimension, its mass discontinuity effectively “displaces” spacetime wherein the spacetime dilation can be considered a “thickness” associated with its gravitational field. Matter and the motion of matter effects the curvature of spacetime which in turn influences the motion of matter. Consider the angular motion of matter of a fundamental particle. The angular momentum of the photon is ℏ. An electron is formed from a photon, and it can only change its bound states in discrete quantized steps caused by a photon at each step. Thus, the electron angular momentum is always quantized in terms of ℏ. But this intrinsic motion comprises a two-dimensional current surface of the motion of the matter through space that may be positively curved, flat, or negatively curved. The first and second cases correspond to the bound and free electron, respectively. The third case corresponds to an extraordinary state of matter called a pseudoelectron given infra. Due to interplay between the motion of matter and spacetime in terms of their respective geometries, only in the first case are the inertial and gravitational masses of the electron equivalent. In the second case, the gravitational mass is zero. The experimental mass of the free electron measured by Witteborn [1] using a free fall technique is less than 0.09 mₑ, where mₑ is the inertial mass of the free electron (9.109534×10⁻³¹ kg) consistent with the Classical Physics theoretical prediction. In the third case, the gravitational mass is negative in the equations of extrinsic or translational motion. The negative gravitational mass of a fundamental particle is the basis of and is manifested as a fifth force that acts on the fundamental particle in the presence of a gravitating body in a direction opposite to that of the gravitational force with far greater magnitude. In the case of Einstein's gravity equation (Eq. (32.40)), the Einstein's Tensor G_{μv}, is equal to the stress-energy-momentum tensor T_{μv}. The only possibility is for the gravitational mass to be equivalent to the inertial mass. A particle of zero or negative gravitational mass is not possible. However, it is shown in the Gravity section that the correct basis of gravitation is not according to Einstein's equation Eq. (32.40); instead, the origin of gravity is the relativistic correction of spacetime itself which is analogous to the special relativistic corrections of inertial parameters—increase in mass, dilation in time, and contraction in length in the direction of constant relative motion of separate inertial frames. On this basis, the observed acceleration of the cosmos is predicted as given in the Cosmology section.

The two-dimensional nature of matter permits the unification of subatomic, atomic, and cosmological gravitation. The theory of gravitation that applies on all scales from quarks to cosmos as shown in the Gravity section is derived by first establishing a metric. A space in which the curvature tensor has the following form:

R_{μv,αβ}=K·(g_{vα}g_{μβ}−g_{μα}g_{vβ}) (35.1)

is called a space of constant curvature; it is a four-dimensional generalization of Friedmann-Lobachevsky space. The constant K is called the constant of curvature. The curvature of spacetime results from a discontinuity of matter having curvature confined to two spatial dimensions. This is the property of all matter at the fundamental-particle scale. Consider an isolated bound electron comprising an orbitsphere with a radius rₙ as given in the One-Electron Atom section. For radial distances, r , from its center with r<rₙ, there is no mass; thus, spacetime is flat or Euclidean. The curvature tensor applies to all space of the inertial frame considered; thus, for r<rₙ, K=0. At r=rₙ there exists a discontinuity of mass in constant motion within the orbitsphere as a positively curved surface. This results in a discontinuity in the curvature tensor for radial distances ≥rₙ . The discontinuity requires relativistic corrections to spacetime itself. It requires radial length contraction and time dilation corresponding to the curvature of spacetime. The gravitational radius of the orbitsphere and infinitesimal temporal displacement corresponding to the contribution to the curvature in spacetime caused by the presence of the orbitsphere are derived in the Gravity section.

The Schwarzschild metric gives the relationship whereby matter causes relativistic corrections to spacetime that determines the curvature of spacetime and is the origin of gravity. The correction is based on the boundary conditions that no signal can travel faster than the speed of light including the gravitational field that propagates following particle production from a photon wherein the particle has a finite gravitational velocity given by Newton's Law of Gravitation. The separation of proper time between two events x^{μ} and x^{μ}+dx^{μ} given by Eq. (32.38), the Schwarzschild metric [2-3], is

$$d {τ}^{2} = ( 1 - \frac{2 {Gm}_{0}}{{c}^{2} r} ) {dt}^{2} - \frac{1}{{c}^{2}} [ {( 1 - \frac{2 {Gm}_{0}}{{c}^{2} r} )}^{- 1} {dr}^{2} + {r}^{2} d {θ}^{2} + {r}^{2} {sin}^{2} θ d {φ}^{2} ] \qquad ( 35.2 )$$

Eq. (35.2) can be reduced to Newton's Law of Gravitation for r_{g}, the gravitational radius of the particle, much less than r*_{α}, the radius of the particle at production

$$( \frac{{r}_{g}}{{r}_{α}^{*}} << 1 ) ,$$

where the radius of the particle is its Compton wavelength bar (r*_{α}=λ_{c}):

$$F = \frac{{Gm}_{1} {m}_{2}}{{r}^{2}} \qquad ( 35.3 )$$

where G is the Newtonian gravitational constant. Eq. (35.2) relativistically corrects Newton's gravitational theory. In an analogous manner, Lorentz transformations correct Newton's laws of mechanics.

The effects of gravity preclude the existence of inertial frames in a large region, and only local inertial frames, between which relationships are determined by gravity are possible. In short, the effects of gravity are only in the determination of the local inertial frames. The frames depend on gravity, and the frames describe the spacetime background of the motion of matter. Therefore, differing from other kinds of forces, gravity which influences the motion of matter by determining the properties of spacetime is itself described by the metric of spacetime. It was demonstrated in the Gravity section that gravity arises from the two spatial dimensional mass-density functions of the fundamental particles.

It is demonstrated in the One-Electron Atom section that a bound electron is a two-dimensional spherical shell—an orbitsphere. On the atomic scale, the curvature, K, is given by

$$\frac{1}{{r}_{n}^{2}} ,$$

where rₙ is the radius of the radial delta function of the orbitsphere. The velocity of the electron is a constant on this two-dimensional sphere. It is this local, positive curvature of the electron that causes gravity due to the corresponding physical contraction of spacetime due to its presence as shown in the Gravity section. It is worth noting that all ordinary matter, comprised of leptons and quarks, has positive curvature. Euclidean plane geometry asserts that (in a plane) the sum of the angles of a triangle equals 180°. In fact, this is the definition of a flat surface. For a triangle on an orbitsphere the sum of the angles is greater than 180°, and the orbitsphere has positive curvature. For some surfaces the sum of the angles of a triangle is less than 180°; these are said to have negative curvature.

| sum of angles of triangles | type of surface |
|---|---|
| >180° | positive curvature |
| =180° | flat |
| <180° | negative curvature |

The measure of Gaussian curvature, K, at a point on a two-dimensional surface is

$$K = \frac{1}{{r}_{1} {r}_{2}} \qquad ( 35.4 )$$

the inverse product of the radius of the maximum and minimum circles, r₁ and r₂, which fit the surface at the point, and the radii are normal to the surface at the point. By a theorem of Euler, these two circles lie in orthogonal planes. For a sphere, the radii of the two circles of curvature are the same at every point and are equivalent to the radius of a great circle of the sphere. Thus, the sphere is a surface of constant curvature;

$$K = \frac{1}{{r}^{2}} \qquad ( 35.5 )$$

at every point. In the case of positive curvature of which the sphere is an example, the circles fall on the same side of the surface, but when the circles are on opposite sides, the curve has negative curvature. A saddle, a cantenoid, a hyperboloid, and a pseudosphere are negatively curved. The general equation of a saddle is

$$z = \frac{{x}^{2}}{{a}^{2}} - \frac{{y}^{2}}{{b}^{2}} \qquad ( 35.6 )$$

where a and b are constants. The curvature of the surface of Eq. (35.6) is

$$K = {\frac{- 1}{4 {a}^{2} {b}^{2}} [ \frac{{x}^{2}}{{a}^{4}} + \frac{{y}^{2}}{{b}^{4}} + \frac{1}{4} ]}^{- 2} \qquad ( 35.7 )$$

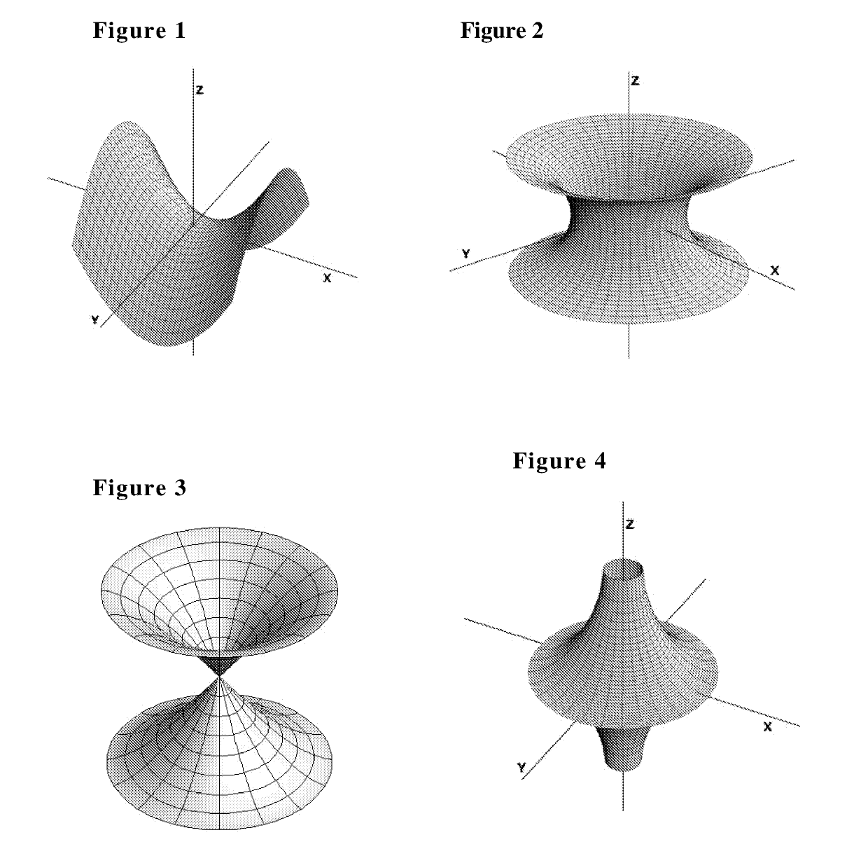

A saddle is shown schematically in FIG. 1, a hyperboloid is shown in FIG. 2, and a conic is shown in FIG. 3.

A pseudosphere is constructed by revolving the tractrix about its asymptote. For the tractrix, the length of any tangent measured from the point of tangency to the x-axis is equal to the height R of the curve from its asymptote—in this case the x-axis. The pseudosphere is a surface of constant negative curvature. The curvature, K

$$K = \frac{- 1}{{r}_{1} {r}_{2}} = \frac{- 1}{{R}^{2}} \qquad ( 35.8 )$$

given by the product of the two principal curvatures on opposite sides of the surface is equal to the inverse of R squared at every point where R is the equitangent. R is also known as the radius of the pseudosphere. A pseudosphere is shown schematically in FIG. 4.

In the case of a sphere, surfaces of constant potential are concentric spherical shells. The general law of potential for surfaces of constant curvature is

$$V = \frac{1}{4 π {ɛ}_{0}} \sqrt{\frac{1}{{r}_{1} {r}_{2}}} = \frac{1}{4 π {ɛ}_{0} R} \qquad ( 35.9 )$$

In the case of a pseudosphere the radii r₁ and r₂, the two principal curvatures, represent the distances measured along the normal from the negative potential surface to the two sheets of its evolute, envelop of normals (cantenoid and x-axis). The force is given as the gradient of the potential that is proportional to

$$\frac{1}{{r}^{2}}$$

in the case of a sphere.

All matter is comprised of fundamental particles, and all fundamental particles exist as mass confined to two spatial dimensions. The particle's current surface is positively curved in the case of an orbitsphere, flat in the case of a free electron, and negatively curved in the case of an electron as a pseudosphere hereafter called a pseudoelectron. The effect of this “local” curvature on the non-local spacetime is to cause it to be Riemannian in the case of an orbitsphere, or hyperbolic, in the case of a pseudoelectron, as opposed to Euclidean in the case of the free electron. Each curvature is manifest as a gravitational field, a repulsive gravitational field, or the absence of a gravitational field, respectively. Thus, the spacetime is curved with constant spherical curvature in the case of an orbitsphere, or spacetime is curved with negative curvature in the case of a pseudoelectron.

Matter arises during particle production from a photon. The limiting velocity c results in the contraction of spacetime due to particle production. The contraction is given by 2πr_{g} where r_{g} is the gravitational radius of the particle. This has implications for the physics of gravitation. By applying the condition to electromagnetic and gravitational fields at particle production, the Schwarzschild metric (SM) is derived from the classical wave equation, which modifies general relativity to include conservation of spacetime in addition to momentum and matter/energy. The result gives a natural relationship between Maxwell's equations, special relativity, and general relativity. It gives gravitation from the atom to the cosmos. The Schwarzschild metric gives the relationship whereby matter causes relativistic corrections to spacetime that determines the curvature of spacetime and is the origin of gravity. The gravitational equations with the equivalence of the particle production energies permit the equivalence of mass-energy and the spacetime wherein a “clock” is defined which measures “clicks” on an observable in one aspect, and in another, it is the ruler of spacetime of the Universe with the implicit dependence of spacetime on matter-energy conversion. The masses of the leptons, the quarks, and nucleons are derived from this metric of spacetime.

The relativistic correction for spacetime dilation and contraction due to the production of a particle with positive curvature is given by Eq. (32.17):

$$f ( r ) = ( 1 - {( \frac{{v}_{g}}{c} )}^{2} ) \qquad ( 35.10 )$$

As shown in the Gravity section (Eq. (32.35)), the derivation of the relativistic correction factor of spacetime was based on the constant maximum velocity of light and a finite positive Newtonian gravitational velocity v_{g} of the particle. The production of a particle requires that the velocity of the particle is equivalent to the Newtonian gravitational escape velocity, v_{g}, of the antiparticle:

$${v}_{g} = \sqrt{\frac{2 {Gm}_{0}}{r}} = \sqrt{\frac{2}{- {λ}_{c}}} \qquad ( 35.11 )$$

From Equation 35.22 and Equations 35.18 through 35.19, the eccentricity is one and the particle production trajectory is a parabola relative to the center of mass of the antiparticle. The right-hand side of Equation 32.43 represents the correction to the laboratory coordinate metric for time corresponding to the relativistic correction of spacetime by the particle production event. Consider a Newtonian gravitational radius, r_{g}, of each orbitsphere of the particle production event, each of mass m₀

$${r}_{g} = \frac{2 {Gm}_{0}}{{c}^{2}} \qquad ( 35.12 )$$

where G is the Newtonian gravitational constant. The substitution of each of Eq. (35.11) and Eq. (35.12) into the Schwarzschild metric Eq. (35.2) gives

$$\begin{matrix}d {τ}^{2} = ( 1 - {( \frac{{v}_{g}}{c} )}^{2} ) {dt}^{2} - \frac{1}{{c}^{2}} [ {( 1 - {( \frac{{v}_{g}}{c} )}^{2} )}^{- 1} {dr}^{2} + {r}^{2} d {θ}^{2} + {r}^{2} {sin}^{2} θ d {φ}^{2} ] & ( 35.13 ) \\ and & \\ d {τ}^{2} = ( 1 - \frac{{r}_{g}}{r} ) {dt}^{2} - \frac{1}{{c}^{2}} [ {( 1 - \frac{{r}_{g}}{r} )}^{- 1} {dr}^{2} + {r}^{2} d {θ}^{2} + {r}^{2} {sin}^{2} θ d {φ}^{2} ] & ( 35.14 )\end{matrix}$$

respectively. The solutions for the Schwarzschild metric exist wherein the relativistic correction to the gravitational velocity v_{g} and the gravitational radius r_{g} are of the opposite sign (i.e. negative). In these cases, the Schwarzschild metric (Eq. (35.2)) is

$$\begin{matrix}d {τ}^{2} = ( 1 + {( \frac{{v}_{g}}{c} )}^{2} ) {dt}^{2} - \frac{1}{{c}^{2}} [ {( 1 + {( \frac{{v}_{g}}{c} )}^{2} )}^{- 1} {dr}^{2} + {r}^{2} d {θ}^{2} + {r}^{2} {sin}^{2} θ d {φ}^{2} ] & ( 35.15 ) \\ and & \\ d {τ}^{2} = ( 1 + \frac{{r}_{g}}{r} ) {dt}^{2} - \frac{1}{{c}^{2}} [ {( 1 + \frac{{r}_{g}}{r} )}^{- 1} {dr}^{2} + {r}^{2} d {θ}^{2} + {r}^{2} {sin}^{2} θ d {φ}^{2} ] & ( 35.16 )\end{matrix}$$

The metric given by Equations 35.13 and 35.14 corresponds to positive curvature. The metric given by Equations 35.15 and 35.16 corresponds to a negative curvature. The positive curvature of spacetime arises from the conversion of a photon traveling at light speed and having no gravitational mass into a bound particle-antiparticle pair such as an electron-positron pair each having its inertial rest mass relative to the corresponding particle's absolute space (Equivalence of Inertial and Gravitational Masses Due to Absolute Space and Absolute Light Velocity section). The escape velocity is the gravitational velocity v_{g} following a parabolic orbit with both particles traveling to an unbound state with relative velocity with respect to the absolute space corresponding to the excess energy over the mass energy of the particles (Gravity section). Both free particles such as leptons and antileptons exist with zero curvature. Each zero-curvature particle is predicted to have a zero gravitational mass and a zero gravitational radius based on continuity of the spacetime metric relationships given by Eqs. (35.13-35.14).

The equations that govern the production and trajectories of fundamental particles (Quantum Gravity of Fundamental Particles section and Particle Production section) also apply to the mechanical equations of existing particles. Bound and free electrons are natural states for inverse-r potentials. Yet, a third extraordinary state is possible for the correspondence between the geometrical form of the mass and the intrinsic motion of particles and their effect on spacetime which in turn affects the extrinsic motion of the particles. Specifically, the particle may possess a negative gravitation radius and a corresponding imaginary velocity. The metric given by Equations 35.13 and 35.14 corresponds to positive curvature; whereas, the metric given by Equations 35.15 and 35.16 corresponds to the extraordinary case of negative curvature. Spacetime having positive curvature in turn affects the extrinsic motion of the negatively curved particle such as one having mass and intrinsic motion confined to a negatively curved two-dimensional membrane in the form of a pseudosphere, pseudoelectron, to give rise to an imaginary translational velocity corresponding to a hyperbolic orbit along the gradient of the positive curvature. Thus, negative gravity (fifth force) can be created by forcing matter into negative curvature. A fundamental particle such as an electron with negative curvature, pseudoelectron, would experience a central but repulsive force with a gravitating body comprised of matter of positive curvature. In this case, the fifth force deflects the pseudoelectron upward such that the negatively curved electron has the translational kinetic energy that causes the coordinate and proper times to be equivalent according to the Schwarzschild metric. Masses and their effects on spacetime superimpose; thus, the metric corresponding to the Earth is given by substitution of the mass of the Earth, M, for m₀ in Equations 35.11 through 35.16. The corresponding Schwarzschild metric Eq. (35.2) is

$$d {τ}^{2} = ( 1 \pm \frac{2 GM}{{c}^{2} r} ) {dt}^{2} - \frac{1}{{c}^{2}} [ {( 1 \pm \frac{2 GM}{{c}^{2} r} )}^{- 1} {dr}^{2} + {r}^{2} d {θ}^{2} + {r}^{2} {sin}^{2} θ d {φ}^{2} ] \qquad ( 35.17 )$$

which is the gravitational mechanics equation that can be expressed in terms of the gravitational velocity v_{g} and the gravitational radius r_{g} as given by Eqs. (35.13-35.16) with the mass being that of the Earth M=5.98×10²⁴ kg .

### Postive, Zero, and Negative Gravitational Mass

The geometry of an electron's 2-dimensional mass surface determines that the electron may have a gravitational mass different from its inertial mass. A bound electron comprising a positively curved mass with its intrinsic surface velocity corresponds to a positive gravitational mass equal to the inertial mass (e.g. particle production or a bound electron). An absolutely free electron comprising a flat surface corresponds to zero gravitational mass with inertial mass mₑ. A pseudoelectron comprising negatively curved mass with its intrinsic surface velocity corresponds to a negative gravitational mass with inertial mass mₑ. Each case is considered in turn infra.

According to Newton's Law of Gravitation, the production of a particle of finite mass gives rise to a gravitational velocity of the particle that is essential in the determination of the particle masses as given in the Quantum Gravity of Fundamental Particles section and Particle Production section. The gravitational velocity of a gravitating body such as the Earth, the velocity of an existing particle, and the nature of its gravitational mass determines the energy, eccentricity, and trajectory of the gravitational orbit of the particle. Consider the case of the equivalence of inertial and gravitational masses. The eccentricity, e, given by Newton's differential equations of motion in the case of the central field (see Equations 32.49 and 32.50) permits the classification of the orbits according to the total energy, E, and according to the orbital velocity, v₀, relative to the Newtonian gravitational escape velocity, v_{g}, as follows [4]. The same relationships hold for trajectories during particle production and motion of existing particles:

$$\begin{matrix}\begin{matrix}E < 0 & e < 1 & ellipse \\ E < 0 & e = 0 & circle ( special case of ellipse ) \\ E = 0 & e = 1 & parabolic orbit \\ E > 0 & e > 1 & hyperbolic orbit\end{matrix} & ( 35.18 ) \\ \begin{matrix}{v}_{0}^{2} < {v}_{g}^{2} = \frac{2 GM}{{r}_{0}} & e < 1 & ellipse \\ {v}_{0}^{2} < {v}_{g}^{2} = \frac{2 GM}{{r}_{0}} & e = 0 & circle ( special case of ellipse ) \\ {v}_{0}^{2} = {v}_{g}^{2} = \frac{2 GM}{{r}_{0}} & e = 1 & parabolic orbit \\ {v}_{0}^{2} > {v}_{g}^{2} = \frac{2 GM}{{r}_{0}} & e > 1 & hyperbolic orbit\end{matrix} & ( 35.19 )\end{matrix}$$

Since E=T+V and is constant, the closed orbits are those for which T<|V|, and the open orbits are those for which T≥|V|. It can be shown that the time average of the kinetic energy, <T>, for elliptic motion in an inverse square field is ½ that of the time average of the potential energy, <V>:<T>=½<V>.

In the case that a particle of inertial mass, m, is observed to have a speed, v₀, a distance from a massive object, r₀, and a direction of motion makes that an angle, φ, with the radius vector from the object (including a particle) of mass, M, the total energy is given by

$$E = \frac{1}{2} {mv}^{2} - \frac{GMm}{r} = \frac{1}{2} {mv}_{0}^{2} - \frac{GMm}{{r}_{0}} = constant \qquad ( 35.20 )$$

The orbit will be elliptic, parabolic, or hyperbolic, according to whether E is negative, zero, or positive. Accordingly, if v₀² is less than, equal to, or greater than

$$\frac{2 GM}{{r}_{0}} ,$$

the orbit will be an ellipse, a parabola, or a hyperbola, respectively. Since h, the angular momentum per unit mass, is

h=L/m=|r×v|=r₀v₀ sin φ (35.21)

the eccentricity, e, from Eq. (32.63) may be written as

$$e = {[ 1 + ( {v}_{0}^{2} - \frac{2 GM}{{r}_{0}} ) \frac{{r}_{0}^{2} {v}_{0}^{2} {sin}^{2} φ}{{G}^{2} {M}^{2}} ]}^{1 / 2} \qquad ( 35.22 )$$

The nature of the sign of the parameters v_{g}² and r_{g} (see Equations 35.13-35.16) with the corresponding mechanics equations determine the behavior of the electron of a given curvature in terms of the classification of the gravitational mass being positive, zero, or negative in the historical Newtonian or general relativistic view. In the last two cases, the inertial and gravitational masses are not equivalent. Consider the first case. The particle production equation (Eq. 32.43) is for isolated particles at infinity wherein the gravitational and inertial masses are equal. A discontinuity in mass in positive curvature gives rise to a discontinuity in the positive curvature of spacetime that is the origin of gravity. Even at infinity relative to each other, each member of a production pair of particles is still in positive curvature due to the charge neutrality condition that requires that the field lines of one particle terminate on the other. The central field exists and maintains a positive curvature that maintains the equivalence of inertial and gravitational masses. The electric and magnetic fields of a particle are considered part of its inertial mass. This inertial mass is released as photons corresponding to the binding energy E_{B} of the oppositely charged particle. So, the sum of the masses of bound particles is less by

$$\frac{{E}_{B}}{{c}^{2}} .$$

The gravitational mass also decreases by this amount since the released photons have no gravitational mass as given in the Deflection of Light section. In a special case, a free electron can be maintained in the essential absence of fields and without spin angular momentum by cancellation with orbital angular momentum such that the curvature is no longer positive, and the inertial and gravitational masses are no longer equivalent.

Minkowski space applies to the free electron. In the Electron in Free Space section, a free electron is shown to be a two-dimensional plane wave—a flat surface. Because the gravitational mass depends on the positive curvature of a particle, a free electron has inertial mass but not gravitational mass. If the electric and magnetic fields are essentially eliminated from a region of vacuum space containing an electron such that the electron is completely free and unbound and the spin angular momentum is cancelled, it may be possible to measure an electron gravitational mass that is less than the inertial mass mₑ. The gravitational mass is zero in the limit of the electron being absolutely free. With the exclusion of electromagnetic fields and the cancelation of the spin angular momentum, Witteborn [1] experimentally measured the gravitational mass of the free electron using a free fall technique. The reported result was less than 0.09 mₑ, where mₑ is the inertial mass of the free electron (9.109534×10⁻³¹ kg). Thus, a free electron is not gravitationally attracted to ordinary matter, and the gravitational and inertial masses are not equivalent. Witteborn [1] explains the observation that free electrons floated in the drift tube by a postulated Schiff-Barnhill effect wherein the electrons in the metal of the drift tube fall in the Earth's gravitational field to produce an electric field which identically balances the force of gravity on the free electrons in the drift tube. This explanation is untenable. The binding energy of electrons in metals is typically 5 eV; whereas, the gravitational potential energy over atomic dimensions is over 20 orders of magnitude less and is given by E=mₑgh where mₑ is the mass of the electron, g is the acceleration of gravity, and h is the metal internuclear spacing, about 10⁻¹⁰ m . The positive nuclei weigh 4,000 times the mass of the electrons. And, this zero mass equivalent electrical force requires the achievement of a perfect Penning trap having 11 orders of magnitude strength match at six-figure accuracy using gravity as the source of trapping field by pure chance!

The reluctance to accept the experimental results of the free electron gravitational mass is that it would violate the Equivalence Principle and disprove general relativity. The original Equivalence Principle put forth by Einstein was the equivalence of an accelerating inertial frame and a gravitational field that was shown to be incorrect and modified by others. This bias is evident in the presentation of the findings of the 2nd International Workshop on Antimatter and Gravity that took place on Nov. 13-15, 2013 at the Albert Einstein Center for Fundamental Physics of the University of Bern. One of the main topics was on the results of the measurement of the gravitational mass of the free electron. The CERN Courier [5] reports:

“Free-fall experiments with charged particles are notoriously difficult because they must be carefully shielded from electromagnetic fields. For example, the sagging of the gas of free electrons in metallic shielding induces an electric field that can counterbalance the effect of gravity. Indeed, measurements based on dropping electrons led to a value of the acceleration of gravity, g, consistent with zero (instead of g=9.8 m/s²).”

Indeed the predicted gravitational mass of the free electron is zero.

Another reservation against the acceptance of the measurement of the zero gravitational mass of the free electron is that under the equivalence principle a perpetual motion scheme could be devised: (1) the free electron is formed with the application of a 13.6 eV photon to a hydrogen atom, (2) the proton and free electron are transported to infinity relative to the Earth, (3) the free electron binds with the proton to return the 13.6 eV photon, (4) the atom comprising a bound electron having a gravitational mass equivalent to the inertial mass falls to the Earth to net produce “free energy” from the added gravitational energy with the free electron becoming gravitationally massive on the return trip. This scenario is an infinitely repeatable cycle; thus, it comprises perpetual motion. The reason why this is not the case is that it requires exactly the gravitation potential energy of the electron's inertial mass to exclude all fields, cancel spin, and form an absolutely free electron. The gravitational energy to completely eliminate any electric field termination on its surface and cancel the spin angular momentum such at it is absolutely free is given by

$$\begin{matrix}{V}_{G} = - \frac{GMm}{r} \\ = - \frac{6.67 \times {10}^{- 11} N \cdot {m}^{2} \text{/} {kg}^{2} ( 9.11 \times {10}^{- 31} kg ) ( 5.98 \times {10}^{24} kg )}{( 6.37 \times {10}^{6} m )} \\ = - 5.70 \times {10}^{- 23} J \\ = - 3.56 \times {10}^{- 4} eV\end{matrix} \qquad ( 35.23 )$$

wherein r=6.37×10⁶ m is the radius of the Earth.

Furthermore, it is possible to give the electron negative curvature to cause a fifth force with negative gravitational mass behavior. Hereto, energy must be applied to form this state so no perpetual motion scheme is possible. The negative mass behavior can be modeled as a hyperbolic trajectory of a pseudoelectron. A particle comprising a gravitating body is the source of local spacetime curvature that is negative in the case of a pseudoelectron. In the presence of the large positive curvature of the Earth, the corresponding gravitational velocity is imaginary, the energy of the orbit of the pseudoelectron must always be greater than zero, the eccentricity is always greater than one, and the trajectory is a hyperbola (Eqs. (35.18-35.19) and (35.22)). The gravitational mass of the pseudoelectron behaves as negative and the inertial mass mₑ is constant (e.g. equivalent to its mass energy given by Eq. (33.13)). The trajectory of pseudoelectrons can be found by solving the Newtonian inverse-square gravitational force equations for the case of a repulsive force caused by pseudoelectron production. The trajectory follows from the Newtonian gravitational force and the solution of motion in an inverse-square repulsive field is given by Fowles [6]. The trajectory can be calculated rigorously by solving the orbital equation from the Schwarzschild metric (Eqs. (35.15-35.16)) for a two-dimensional spatial mass-density function of negative curvature which is repelled by the Earth. The rigorous solution is equivalent to that given for the case of a positive gravitational velocity given in the Orbital Mechanics section except that the gravitational velocity is imaginary and the magnitude is determined by the negative curvature.

In the case of a mass of negative curvature, Eq. (32.77) becomes

$${E}_{g} = + \frac{GMm}{r} \qquad ( 35.24 )$$

where M is the mass of the Earth and m is the gravitational mass of the pseudoelectron that is negative, different from its inertial mass, and depends on the negative curvature. The negative curvature is determined by the Gaussian curvature, K, at a point on a two-dimensional surface given by Eqs. (35.4-35.5) and (35.8). According to Eqs. (32.48), (32.140) and (32.43), matter, energy, and spacetime are conserved with respect to creation of the pseudoelectron which is repelled from a gravitating body (e.g. the Earth). The ejection of a pseudoelectron having a negatively curved mass surface from the Earth must result in an infinitesimal decrease in the radius of the Earth (e.g. r of the Schwarzschild metric given by Eq. (35.2) where m₀=M is the mass of the Earth, 5.98×10²⁴ kg). The amount that the gravitational potential energy of the Earth is lowered is equivalent to the total energy gained by the repelled pseudoelectron. As an offsetting contribution to the curvature inventory, the conversion of matter to energy to produce the photon that excites the pseudoelectron state causes spacetime expansion according to Eq. (32.140). Upon decay, the energy is available to be absorbed to increase the equivalent inertial and gravitational masses of matter in positive curvature. Momentum is also conserved for the pseudoelectron and Earth, wherein the latter gravitating body that repels the pseudoelectron, receives an equal and opposite change of momentum with respect to that of the electron. As a familiar example, causing a satellite to follow a hyperbolic trajectory about a gravitating body is a common technique to achieve a gravity assist to further propel the satellite. In this case, the energy and momentum gained by the satellite are also equal and opposite those lost by the gravitating body. Unlike the electric and magnetic forces where the vector corresponding to the opposite sign of charge or opposite magnetic pole has the same magnitude, the magnitude of the fifth force acting on a fundamental particle can be much greater than the gravitational force acting on the same inertial mass when the inertial and gravitational masses are equivalent. It depends on the extent of the negative curvature forced onto the pseudoelectron. The amount of energy and power applied to maintain the extent of negative curvature of a pseudoelectron and a plurality of pseudoelectrons determines the lift. Next, the mathematical structure, nature, and energies of the pseudoelectron will be elucidated.

### Determination of the Properties of Electrons, Those of Constant Negative Curvature, and Those of Pseudoelectrons

The candidates for a negatively curved electron state are shown in FIGS. 35.1-35.4. By rotating a curve in the xz-plane about the z-axis, an exemplary surface of revolution with constant Gaussian curvature having K=−1 is generated. Consider that the Cartesian coordinate curve profile is given by

c(t)=(x(t),0,z(t)) (35.25)

parameterized by arc length

x′(t)²+z(t)²=1 (35.26)

The Gaussian curvature of the corresponding surface of revolution

f(u,v)=(x(u)cos v,x(u)sin v,z(u)) (35.27)

is then given by

$$K ( u , v ) = \frac{{x}^{″} ( u )}{x ( u )} = - 1 \qquad ( 35.28 )$$

Since K=−1 is a constant, Eq. (35.28) gives rise to the second-order differential equation:

x″(t)+x(t)=0 (35.29)

that is solved analytically to give

x(t)=ae^{t}+be^{-t} (35.30)

where a and b are constants to match boundary conditions. The corresponding function z is then calculated from Eq. (35.26) by numerical integration to give the surface shown in FIG. 35.5 [7]. Alternatively, the analytical expressions are given by M. Spivak [8] for the case of a=−b:

$$\begin{matrix}x ( t ) = a ( {e}^{t} - {e}^{- t} ) = 2 a sinh t & ( 35.31 ) \\ z ( t ) = \pm {\int }_{0}^{t} \sqrt{1 - 4 {a}^{2} {cosh}^{2} t} dt & ( 35.32 )\end{matrix}$$

wherein 0<2a<1 and 1≤cosh t≤1/2a, so that 0≤cosh⁻¹1/2a and 0≤g(t)≤√1−4a². These are functions that can be expressed in terms of elliptic integrals with results shown in FIG. 35.5.

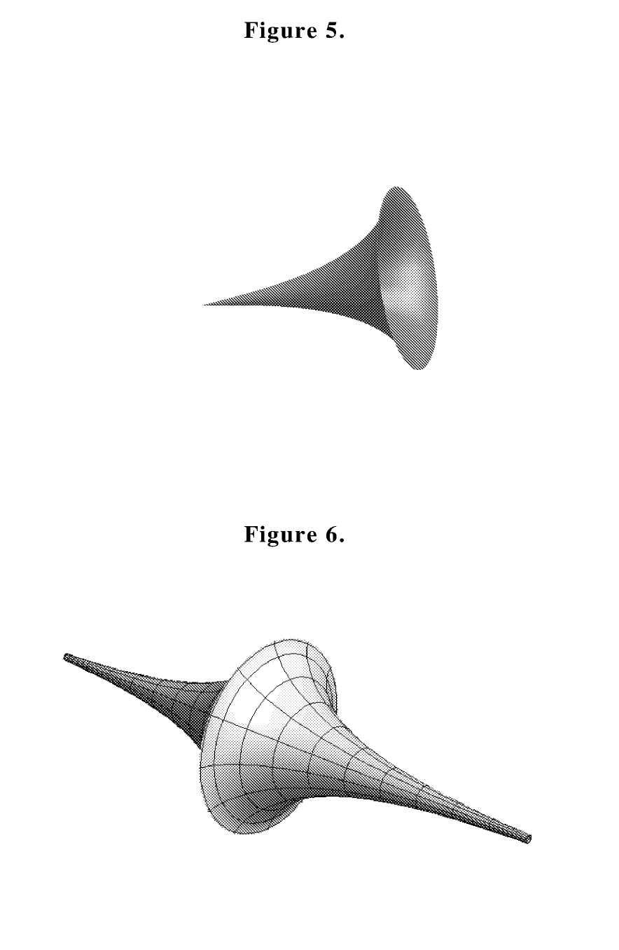

A free electron avoids a singularity by having the current density approaching zero at the extrema. A nonphysical aspect of the candidate shown in FIG. 5 having a negatively curved surface is the singularities at the extrema. FIG. 5 depicts the half-space surface rendering of a constant Gaussian curvature K=−1. The complete surface comprises additionally the mirror image. In contrast, the pseudosphere (FIG. 6) generated by rotating the tractrix about the asymptote avoids such a singularity and maintains current continuity at infinity. That is, the pseudosphere shows rulings of the tractrix along the asymptote axis. The mass goes to zero at the extrema at infinity since the corresponding area goes to zero, the current has an increasing azimuthal component at the extrema at infinity to maintain continuity, and relativistic effects cause the asymptotic span to be finite. Moreover, the constant radius R of the pseudosphere is permissive of a central force balance that is stable to radiation and conserves the electron angular momentum of ℏ as shown in the Fourier Transform of the Pseudoelectron Current Density section and the Force Balance and Electrical Energies of Pseudoelectron States section. The nature of a pseudoelectron comprising an autonomous electron with a bound photon to maintain its surface of constant negative curvature can be appreciated by comparing it to other photon-electron states and the nature of the unnormalized orbitsphere current density distribution shown in FIG. 1.20 and the normalized one shown in FIG. 1.21.

### Nature of Photonic Super Bound Hydrogen States and the Corresponding Continuum Extreme Ultraviolet (EUV) Transition Emission and Super Fast Atomic Hydrogen

J. R. Rydberg showed that all of the spectral lines of atomic hydrogen were given by a completely empirical relationship:

$$\overline{v} = R ( \frac{1}{{n}_{f}^{2}} - \frac{1}{{n}_{i}^{2}} ) \qquad ( 35.33 )$$

where R=109,677 cm⁻¹, n_{f}=1,2,3, . . . , n₁=2,3,4, . . . and nᵢ>n_{f}. Bohr, Schrödinger, and Heisenberg, each developed a theory for atomic hydrogen that gave the energy levels in agreement with Rydberg's equation.

$$\begin{matrix}{E}_{n} = - \frac{{e}^{2}}{{n}^{2} 8 π {ɛ}_{o} {a}_{H}} = - \frac{13.598 eV}{{n}^{2}} & ( 35.34 ) \\ n = 1 , 2 , 3 , … & ( 35.35 )\end{matrix}$$

where e is the elementary charge, ε₀ is the permittivity of vacuum, and a_{H} is the radius of the hydrogen atom. The Rydberg equation is a simple integer formula that empirically represents the Rydberg series of spectral lines, the entire hydrogen spectrum given in terms of the differences between all of the principal energy levels of the hydrogen atom.

The excited energy states of atomic hydrogen are given by Eq. 35.35 for n>1 in Eq. 35.34. The n=1 state is the “ground” state for “pure” photon transitions (i.e. the n=1 state can absorb a photon and go to an excited electronic state, but it cannot release a photon and go to a lower-energy electronic state). However, an electron transition from the ground state to a lower-energy state may be possible by a resonant nonradiative energy transfer such as multipole coupling or a resonant collision mechanism. Processes such as hydrogen molecular bond formation that occur without photons and that require collisions are common [9]. Also, some commercial phosphors are based on resonant nonradiative energy transfer involving multipole coupling [10]. Specifically, atomic hydrogen may undergo a catalytic reaction with certain atomized elements and ions which singly or multiply ionize at integer multiples of the potential energy of atomic hydrogen, m·27.2 eV wherein m is an integer. The predicted reaction involves a resonant, nonradiative energy transfer from otherwise stable atomic hydrogen to the catalyst capable of accepting the energy. The product is H (1/p) , fractional Rydberg states of atomic hydrogen called “hydrino atoms” wherein

$$n = \frac{1}{2} , \frac{1}{3} , \frac{1}{4} , … , \frac{1}{p}$$

(p≤137 is an integer) replaces the well-known parameter n=integer in the Rydberg equation for hydrogen excited states.

The n=1 state of hydrogen and the

$$n = \frac{1}{integer}$$

states of hydrogen are nonradiative, but a transition between two nonradiative states, say n=1 to n=½, is possible via a nonradiative energy transfer. Hydrogen is a special case of the stable states given by Eqs. (35.34) wherein the corresponding radius of the hydrogen or hydrino atom is given by

$$r = \frac{{a}_{H}}{p} , \qquad ( 35.36 )$$

where p=1,2,3, . . . In order to conserve energy, energy must be transferred from the hydrogen atom to the catalyst in units of

m·27.2 eV, m=1,2,3,4 . . . (35.37)

and the radius transitions to

$$\frac{{a}_{H}}{m + p} .$$

The catalyst reactions involve two steps of energy release: a nonradiative energy transfer to the catalyst followed by additional energy release as the radius decreases to the corresponding stable final state. Thus, the general reaction is given by

$$\begin{matrix}m \cdot 27.2 eV + {Cat}^{q +} + H [ \frac{{a}_{H}}{p} ] \to {Cat}_{fast}^{( q + r ) +} + {re}^{-} + H * [ \frac{{a}_{H}}{( m + p )} ] + m \cdot 27.2 eV & ( 35.38 ) \\ H * [ \frac{{a}_{H}}{( m + p )} ] \to H [ \frac{{a}_{H}}{( m + p )} ] + [ {( p + m )}^{2} - {p}^{2} ] \cdot 13.6 eV - m \cdot 27.2 eV & ( 35.39 ) \\ {Cat}_{fast}^{( q + r ) +} + {re}^{-} \to {Cat}^{q +} + m \cdot 27.2 eV & ( 35.40 )\end{matrix}$$

And, the overall reaction is

$$H [ \frac{{a}_{H}}{p} ] \to H [ \frac{{a}_{H}}{( m + p )} ] + [ {( p + m )}^{2} - {p}^{2} ] \cdot 13.6 eV \qquad ( 35.41 )$$

q, r, m, and p are integers.

$$H * [ \frac{{a}_{H}}{( m + p )} ]$$

has the radius of the hydrogen atom (corresponding to 1 in the denominator) and a central field equivalent to (m+p) times that of a proton, and

$$H [ \frac{{a}_{H}}{( m + p )} ]$$

is the corresponding stable state with the radius of

$$\frac{1}{( m + p )}$$

that of H. As the electron undergoes radial acceleration from the radius of the hydrogen atom to a radius of

$$\frac{1}{( m + p )}$$

this distance, energy is released as characteristic light emission or as third-body kinetic energy. The emission may be in the form of an extreme-ultraviolet continuum radiation having an edge at [(p+m)²−p²−2m]·13.6 eV or

$$\frac{91.2}{[ {( p + m )}^{2} - {p}^{2} - 2 m ]} nm$$

and extending to longer wavelengths [11-17]. In addition to radiation, a resonant kinetic energy transfer from

$$H * [ \frac{{a}_{H}}{( m + p )} ]$$

to form fast H may occur by an inverse Franck-Hertz mechanism [18] involving H atoms rather than electrons that are selective for H based on resonant dipole induction and H being the most efficient momentum acceptor having the least mass of any atom (See the Dipole-Dipole Coupling section). Subsequent excitation of these fast H (n=1) atoms by collisions with the background gases followed by emission of the corresponding H (n=3) atoms gives rise to broadened Balmer α emission. Fast H may also arise from the production of fast protons that conserve the potential energy of the catalyst that is ionized during the energy transfer wherein the catalyst comprises a source of H such as HOH or nH (n is an integer) catalyst. The fast protons recombine with electrons to give the characteristic Doppler broadened atomic H lines such as broadened Balmer alpha emission observed experimentally [19-25].

Visible photons and extremely high-energy photons, respectively, may excite the formation of photon bound, autonomous electron states such as spherical states in liquid media and inverse spherical states in vacuum or gas. The former case regards the formation of photon bonding of an orbitsphere current density function as given in the One Electron Atom section. In the latter case, a free electron is in a nonradiative bound state comprising geometry that is the inverse of a bound excited state. Specifically, a free electron may form an inverse spherical bound state of pseudospherical mass, charge, and surface current density bound by a trapped photon that travels along the two-dimensional electron surface as in the case of the excited states, but the photon field is repulsive rather than attractive, such that the direction of the centrifugal forces is also opposite the spherical case. Here, the energy to form the stable bound state is not due to a negative electrostatic potential. Rather, the binding energy is due to the negative gravitational potential energy that arises from the mass, charge, and current density surface in negative curvature. The pseudospherical electron state is referred to as a pseudoelectron. The formation of a pseudoelectron requires the presence of a gravitating body wherein the gravitational energy is conserved between the gravitating body and the pseudoelectron. Specifically, the positive curvature of spacetime due to the gravitating body is increased causing a more negative gravitational energy in response to the negative curvature contribution of the pseudoelectron that consequently experiences a force to eject it from the spacetime in proximity to the gravitating body. The change in positive curvature and corresponding gravitational field propagate as a light-like wave as in the case with particle production given in the Quantum Gravity of Fundamental Particles section.

### Nature of Photon-Bound Autonomous Electron States

As shown in the Free Electrons in Superfluid Helium are Real in the Absence of Measurement Requiring a Connection of Ψ(x) to Physical Reality section, free electrons are trapped in superfluid helium as autonomous electron bubbles interloped between helium atoms that have been excluded from the space occupied by the bubble [26-29]. The surrounding helium atoms maintain the spherical bubble through van der Waals forces. Each spherical electron cavity comprises an orbitsphere that can act as a resonator cavity. The excitation of the Maxwellian resonator cavity modes by resonant photons forms bubbles with radii of reciprocal integer multiples of that of the unexcited n=1 state. The central force that results in a fractional electron radius compared to the unexcited electron is provided by the absorbed photon. Each stable excited state electron bubble that has a radius of

$$\frac{{r}_{1}}{integer}$$

may migrate in an applied electric field. The photo-conductivity absorption spectrum of free electrons in superfluid helium and their mobilities predicted from the corresponding size and multipolarity of these long-lived bubble-like states with quantum numbers n, l, and mₗ matched the experimental results of the 15 identified ions [26].

In addition to superfluid helium, free electrons also form bubbles devoid of any atoms in other fluids such as oils and liquid ammonia. In the operation of an electrostatic atomizing device, Kelly [30] observed that with plasma light irradiation the mobility of free electrons in oil increased by an integer factor rather than continuously. Certain metals such as alkali metals that have low ionization energy dissolve as ions and free electrons in liquid ammonia and certain other solvents. As in the case of free electrons in superfluid helium, ammoniated free electrons form cavities devoid of ammonia molecules having a typical diameter of 3-3.4 Å. The cavities are evidenced by the observation that the solutions are of much lower density than the pure solvent. From another perspective, they occupy far too great a volume than that predicted from the sum of the volumes of the metal and solvent. The electrolytically conductive solutions have free electrons of extraordinary mobility as their main charge carriers [31]. In very pure liquid ammonia the lifetime of free electrons can be significant with less than 1% decomposition per day. The confirmation of their existence as free entities is given by their broad absorption around 15,000 Å that can only be assigned to free electrons in the solution that is blue due to the absorption. In addition, magnetic and electron spin resonance studies show the presence of free electrons, and a decrease in paramagnetism with increasing concentration is consistent with spin pairing of electrons to form diamagnetic pairs.

In the case of vacuum, there is no solvent sphere; consequently, new physics may be observed with high energy irradiation of electrons, namely the formation of pseudoelectrons each comprising a pseudospherical charge and current density membrane held in force balance by a trapped photon. In the case of free electrons in a liquid medium such as superfluid helium, ammonia, or oil, the geometry is driven by minimization of the surface to volume ratio similar to the case with surface tension of bubble films. In contrast, the formation of a pseudoelectron depends on maximizing the negative gravitational potential energy that also results in the further minor energy contribution to stability of the minimization of the electric self-field energy. This occurs by maximizing the surface to volume ratio to diffuse the electric field. By both mechanisms, the energy stability is achieved by minimizing the pseudosphere volume (Eq. (35.100)) that also maximizes the curvature K of pseudoelectron having a R⁻² dependency where R is the pseudoelectron radius (Eq. (35.8)). In addition, the nature of the absorbed photon of the particular electronic state determines its stability or instability wherein the nature of the absorbed photon is dependent on the geometry or curvature of the electron comprising a 2-D current membrane, any nuclear field, and the energy of the state.

As shown by Eqs. 35.38-35.41, the photonic contribution to the central field of a hydrino is positive. Specifically, at the position of the electron, the photon field provides the equivalent of a positive integer increase to the central field of the proton Eq. 35.27 that gives rise to a radial monopole (Eq. (6.9)). Conversely, at the position of the electron, the excited state photon field comprises the superposition of two components, the negative equivalent of the central field of the proton and a positive reciprocal integer times the equivalent of the central field of the proton (Eqs. (2.12-2.17)). The opposing components give rise to the sum of a radial dipole (Eq. (2.25))) and a positive spherical and time harmonic monopole having the field equivalents of the fundamental charge and a fraction of the fundamental charge, respectively. The photonic central field of the pseudoelectron is purely negative; thus, the photon field gives rise to a corresponding pure radial monopole at the position of the electron. The stability of the pseudoelectron (Eqs. (35.72)) versus the instability of an electronic excited state (Eqs. (2.29-2.35)) arises from the different states having negative curvature versus positive curvature, respectively. The different geometries cause the corresponding current densities to be absent and possess Fourier components synchronous with waves traveling at the speed of light, respectively, that determine stability to radiation as given in the Fourier Transform of the Pseudosphere Current Density section.

The radiative states comprise the hydrino intermediate (atomic hydrogen following energy transfer to a catalyst), excited states, and free electron states undergoing acceleration wherein the mechanism of charge acceleration may be generalized to all three cases. The nonradiative cases are hydrogen (n=1 state), hydrino states, spherical states in a liquid medium, these states with an absorbed photon, and free electrons at rest or constant velocity. The lifetime of the pseudoelectron state may be long as it is in the case of the continuum excited states of free electrons comprising a bound photon and negative gravitational potential energy to maintain the state with kinetic energy equal to ½ the excitation energy as shown in the Classical Physics of the de Broglie Relation section.

### Pseudoelectrons

Surfaces shown in FIGS. 1 through 4 are candidates for a negatively curved electron state to produce the sought negative gravitational force according to Eqs. 35.15-35.16. The boundary constraints are a surface of constant negative Gaussian curvature and capable of binding a photon and maintaining mechanical and electrical force balance with the relativistic photon field normal to the electron surface as given in the Equation of the Electric Field inside the Orbitsphere section, relativistic invariance and total energy conservation of the equation of motion on the surface, and stability of the current to radiation. Let's first solve the equivalent of the great circle current loop of the Orbitsphere Equation of Motion for l=0 Based on the Current Vector Field (CVF) section in hyperbolic coordinates. By rotating a curve in the xz-plane about the z-axis, an exemplary surface of revolution with constant Gaussian curvature having K=−1 is generated. Consider that the alternative Cartesian coordinate curve profile given by Eqs. (35.25-35.30) for the case of a=1 and b=0. Eq. (35.30) becomes

x(t)=ae^{t} (35.42)

Using Eq. (35.26), Eq. (35.32) becomes

$$z ( t ) = \pm {\int }_{0}^{t} \sqrt{1 - {e}^{2 t}} dt \sqrt{1 - {e}^{2 t}} - {cosh}^{- 1} ( {e}^{- t} ) \qquad ( 35.43 )$$

replacing some variables gives the xz-cross section of a pseudosphere shown in FIG. 35.6 having the equation:

$$z = \sqrt{1 - {x}^{2}} - {cosh}^{- 1} \frac{1}{x} \qquad ( 35.44 )$$

A pseudosphere also called a tractroid, tractricoid, antisphere, or tractrisoid comprises a negative-Gaussian curvature surface K=−1 of revolution generated by a tractrix in the xy-plane about its asymptote, the z-axis. The pseudosphere of radius r>0 is the image R(R×[0,2π]) having Cartesian parametric equations of

$$r ( u , v ) = \underline{e} ( \begin{matrix}r sech ( u ) cos ( v ) \\ r sech ( u ) sin ( v ) \\ ru - r {tanh}^{2} ( u )\end{matrix} ) \qquad ( 35.45 )$$

for u∈(−∞,∞) and v∈[0,2π) . Alternatively, the pseudosphere can be expressed in Cartesian form as

$${z}^{2} = {[ R {sech}^{- 1} ( \frac{\sqrt{{x}^{2} + {y}^{2}}}{R} ) - \sqrt{{R}^{2} - {x}^{2} - {y}^{2}} ]}^{2} \qquad ( 35.46 )$$

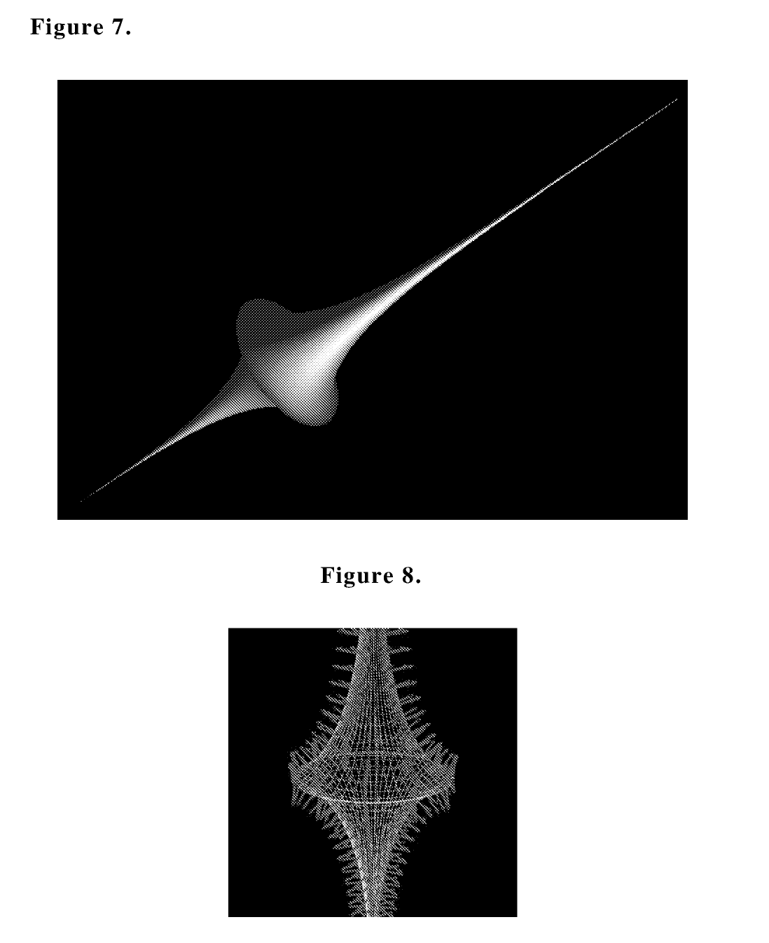

A pseudoelectron shown in FIGS. 6 and 7 comprises a pseudospherical plane lamina of charge and current density comprising a minimum total energy surface having constant negative curvature of K=−1. The pseudospherical membrane is bound by a high-energy photon. The absorbed photon of the pseudoelectron provides a repulsive central electric field that maintains the pseudoelectron in force balance between the centrifugal and corresponding electrostatic force wherein the directions of the centrifugal and electrostatic forces relative to the direction along the central radius are opposite those of hydrino and excited states, and negative binding energy is from the negative gravitational potential energy of the state of constant negative curvature.

The pseudosphere is a solution of the sine-Gordon equation. Consider that the pseudosphere may be described as a map \vec{x}(u, v) from a patch to the surface. If the map is parametrized by arclength along asymptotic lines, then the first fundamental form for the pseudosphere is

I=d\vec{x}·d\vec{x}=du²+2 cos φdudv+dv² (35.47)

Similarly, the second fundamental form is

$$II = d \vec{x} \cdot d \vec{N} = \frac{2}{ρ} sin φ dudv \qquad ( 35.48 )$$

Application of the Codazzi-Mainardi equations then yields [32]

$${φ}_{uv} = \frac{1}{ρ} sin φ \qquad ( 35.49 )$$

which is the sine-Gordon equation that can be written as

$$\frac{{δ}^{2}}{δ {t}^{2}} φ - \frac{{δ}^{2}}{δ {x}^{2}} φ + sin φ = 0 \qquad ( 35.50 )$$

The sine-Gordon equation also meets the prerequisite of being invariant under Lorentz transforms. The relevant Lorentz transforms are

$$\begin{matrix}{t}^{′} = γ ( t - \frac{vx}{{c}^{2}} ) & ( 35.51 ) \\ {x}^{′} = γ ( x - vt ) & ( 35.52 ) \\ {y}^{′} = y & ( 35.53 ) \\ {z}^{′} = z & ( 35.54 )\end{matrix}$$

wherein the inverse Lorentz transformations are given by interchanging the primed and unprimed variables and changing the sign of the velocity. The spacetime sine-Gordon equation (Eq. (35.50)) can be expressed in spacetime coordinates as

φₙ−φₓₓ+sin φ=0 (35.55)

Using the consideration that γ is a constant, Eq. (35.55) can be expressed in the primed coordinates using the following relationships of the time-coordinate:

$$\begin{matrix}{ϕ}_{{t}^{′}} = {ϕ}_{t} \frac{dt}{{dt}^{′}} = γ {ϕ}_{t} & ( 35.56 ) \\ {ϕ}_{{t}^{′} {t}^{′}} = \frac{δ γ}{δ {t}^{′}} {φ}_{t} + γ {ϕ}_{tt} \frac{δ γ}{δ {t}^{′}} = {γ}^{2} {ϕ}_{tt} & ( 35.57 )\end{matrix}$$

The corresponding space-coordinate relationship is

φ_{x′x′}=γ²φₓₓ (35.58)

Using Eqs. (35.55-35.58), the transformed sine-Gordon equation is

$${ϕ}_{{t}^{′} {t}^{′}} - {ϕ}_{{x}^{′} {x}^{′}} + \frac{1}{{γ}^{2}} sin φ = 0 \qquad ( 35.59 )$$

The equations of motion of matter and energy that are a solution of the sine-Gordon equation obey the laws the universe wherein higher velocity gives rise to relativistic length contraction and mass increase of the electron mass density function as given in the Special Relativistic Effect on the Electron Radius and the Relativistic Ionization Energies section.

The sine-Gordon equation can be derived from the Lagrangian with the proper setting of the potential energy function. The general physical energy equations of the current and mass density of the electron are given by the classical Lagrangian that obeys the principle of least action corresponding to conservation of the total energy:

L=δᵤδ^{u}φ−U(φ) (35.60)

The corresponding general physical equations of motion are

$${δ}_{u} {δ}^{u} φ + ( \frac{δ U}{δ φ} ) = 0 \qquad ( 35.61 )$$

The function φ is the spacetime mass and current density function of the negatively curved electron. It is also the spacetime function of the photon field that is in phase with the electron density functions and maintains the force balance. The surface is equal energy, but not equipotential. The potential is given by

U=cos φ (35.62)

Considering one spatial and time dimension corresponding to one current loop the equation of motion becomes the sine-Gordon equation given by Eq. (35.50).

The sine-Gordon equation meets the prerequisite of being of the proper form for governing motion of mass and electromagnetic fields comprising a surface of negative curvature. The sine-Gordon equation is a hyperbolic, nonlinear wave equation in 1+1 dimensions having solutions of surfaces of constant negative curvature constant negative Gaussian curvature K=−1, also called pseudospherical surfaces. The solutions φ(x,t) of Eq. (35.50) determine the internal Riemannian geometry of surfaces of constant negative scalar curvature R=−2, given by the line-element

$${ds}^{2} = {sin}^{2} ( \frac{φ}{2} ) {dt}^{2} + {cos}^{2} ( \frac{φ}{2} ) {dx}^{2} \qquad ( 35.63 )$$

where the angle φ describes the embedding of the surface into Euclidean space R³ [33]. Another common terminology regarding the pseudosphere is the hyperboloid model of the hyperbolic plane wherein the hyperboloid is referred to as a pseudosphere since the hyperboloid can be thought of as a sphere of imaginary radius, embedded in a Minkowski space. Like the orbitsphere of centrally bound states, the pseudoelectron is stable to radiation; thus, it satisfies all of the boundary conditions.

### Fourier Transform of the Pseudoelectron Current Density

Both the atomic excited state photon and the pseudoelectron photon have at least a component of negative radially directed central field that gives rise to a radiative electric dipole in the case of an excited state as shown by Fourier transform analysis in the Instability of Excited States section. However, in contrast to the atomic excited state electron, the radial field corresponds to a monopole, and the radiative stability of the pseudoelectron can be shown by the absence of Fourier components k=ω/c of the spacetime Fourier transform of the pseudoelectron current density function given by Eq. (35.72) with the constant current having angular frequency given by Eq. (35.85) integrated over the parameter u . Due to the constancy of the current that is required to maintain a constant total energy, the time dependent local current fluctuations are zero such that the corresponding Fourier transform is zero. Thus, radiative components k=ω/c do not exist.

Consider the alternative pseudospherical Cartesian parametric equations of

$$\begin{matrix}x = R cos ( u ) sin ( v ) & ( 35.64 ) \\ y = R sin ( u ) sin ( v ) & ( 35.65 ) \\ z = R ( cos ( v ) + ln [ tan ( \frac{1}{2} v ) ] ) & ( 35.66 )\end{matrix}$$

for u∈(0, 2π) and v∈(0,π) . The Fourier transform of the pseudosphere K(s) may be obtained by expressing the Fourier transform in pseudospherical coordinates using (Eqs. (35.64-35.66)) and the Jacobian:

$$J ( v ) = - {R}^{2} cos ( v ) ln [ tan ( \frac{v}{2} ) ] sin ( v ) \qquad ( 35.67 )$$

The integrals over the parametric variables u and v are

$$K ( s ) = - {R}^{2} {\int }_{0}^{π} {\int }_{0}^{2 π} cos ( v ) ln [ tan ( \frac{v}{2} ) ] sin ( v ) exp [ - 2 π isR cos ( u ) sin ( v ) dudv \qquad ( 35.68 )$$

The integration over u given by Mathematica is

$$K ( s ) = - 2 π {R}^{2} {\int }_{0}^{π} {J}_{0} ( 2 π sR sin ( v ) ) cos ( v ) ln [ tan ( \frac{v}{2} ) ] sin ( v ) dv \qquad ( 35.69 )$$

The integration over v is not analytically computable by Mathematica. However, Eq. (35.69) may be integrated as a power series expansion about v=0:

$$K ( s ) = - 2 π {R}^{2} ( \begin{matrix}\frac{1}{4} ( - 1 - 2 ln 2 + 2 ln π ) {π}^{2} \\ + \frac{1}{192} ( \begin{matrix}12 + 3 {( 2 π sR )}^{2} + 4 {( 2 π sR )}^{2} ln 8 \\ + 4 ln 256 - 32 ln π - 12 {( 2 π sR )}^{2} ln π\end{matrix} ) {π}^{4} \\ + {O [ π ]}^{5}\end{matrix} ) \qquad ( 35.70 )$$

Next, the constant time function must be considered. The constant current is given by the charge density multiplied by the constant angular frequency and a constant time function. The Fourier transform of a constant time function [34] is:

$$\frac{x ( t ) = {\int }_{- ∞}^{∞} X ( f ) {e}^{j 2 π f t} df X ( t ) = {\int }_{- ∞}^{∞} x ( t ) {e}^{- j 2 π f t} dt}{1 ⇔ δ ( f ) } \qquad ( 35.71 )$$

A very important theorem of Fourier analysis states that the Fourier transform of a product is the convolution of the individual Fourier transforms [35]. Treating the radial monopole due to the pseudoelectron photon-electron interface, the spacetime Fourier transform of the pseudoelectron current density function P(s) is given by the convolution of the Fourier transforms of the current density alone (Eq. (35.70)) and the time function alone (Eq. (35.71)). The convolution of the frequency delta function of Eq. (35.71) with P(s) (Eq. (35.72)) replaces the frequency variable with zero which is zero:

P(s)=ωK(s)⊗δ(ω)=0K(s)=0 (35.72)

Thus, when the light-like condition of Eq. (Ap.I.43) is applied, the spacetime Fourier transform of the pseudoelectron current density function (Eq. (35.72)) is absent Fourier components k=ω/c due to the absence of the equivalent of time and spherically harmonic current components of atomic electronic excited states. There are no time fluctuations of the current. Rather, it is constant in spacetime having zero as the corresponding Fourier transform.

### Force Balance and Electrical Energies of Pseudoelectron States

Unlike the case wherein photons are released spontaneously by minimization of the energy in a positive R⁻² field such as during emission of an excited state or during a hydrino transition corresponding to the inverse of an excited state, the potential energy and kinetic energy of the pseudoelectron are both positive. The total energy must be negative in order for the pseudoelectron to be stable, and the negative energy requirement for stability is satisfied when the negative gravitational energy exceeds the total energy according to Eq. (35.97).

The force balance of the pseudoelectron is provided by a trapped photon having an electric field at the inner pseudospherical surface corresponding to the electric potential given by Eqs. 35.74 and 35.77. The far-field of the free electron and the far-field of a pseudoelectron are each that of a point charge at the origin along the z-axis, the axis perpendicular to the plane of the free electron and the axis in the plane perpendicular to the asymptote of the pseudoelectron, respectively. The pseudoelectron (PE) transition is excited by a linearly polarized photon corresponding to zero angular momentum. The transition is similar to the spherical transition with Δmₗ=0 (Eq. 2.71). Based on the symmetry of the pseudoelectron across the plane perpendicular to the asymptote (yz plane), the cross section is highest for the photon propagating along the z-axis. The angular dependence of the pseudoelectron excitation can be calculated by substituting the photon-e&mvf for the helium atom in the elastic scattering of a free electron from helium as given in the Electron Scattering for Helium Based on the Orbitsphere Model section. The photon electric field is predominantly forward scattered as shown by Eq. (8.57) and FIG. 8.8.

The photon that maintains the force balance of the pseudoelectron exists only at the inner surface of the pseudoelectron describe by a Dirac delta function such as given by Eq. (2.15) with the spherical radius replaced by the pseudospherical radius r(u,v) (Eq. (35.45)). The charge, current, and angular momentum are finite integratable without incurring infinites at the extrema of the asymptote such that thee average electric field density due to the trapped photon is the same as that of a spherical excited electronic state. Specifically, the area A of the electron orbitsphere and the pseudoelectron are equivalent:

A=4πR² (35.73)

wherein R is the radius of the electron orbitsphere and also the pseudoelectron. A Gauss's-law approach gives an average wherein the average electric field density due to the trapped photon matches that of a spherical excited electronic state.

$${E}_{photon} = \frac{- Ze}{4 π {ɛ}_{0} {R}^{2}} δ ( r - r ( u , v ) ) \hat{N} \qquad ( 35.74 )$$

However, unlike the case of a sphere, the surface area of the pseudosphere is not independent of the position on the surface. The area element dA is

dA=R²sech u|tanh u|dudv=2πR²sech u|tanh u|du (35.75)

The normalized area element variation along the pseudosphere current loop is

$$dA = \frac{{R}^{2} sech u \vert tanh u \vert du}{2} \qquad ( 35.76 )$$

Thus, the normal electric field as a function of area position on the current loop of the pseudosphere is

$${E}_{photon} ( u ) = \frac{- Ze}{4 π {ɛ}_{0} {R}^{2}} \frac{2}{sech u \vert tanh u \vert du} δ ( r - r ( u , v ) ) \hat{N} \qquad ( 35.77 )$$

wherein \hat{N} is the pseudosphere surface normal vector and r(u,v) is given by Eq. (35.45). The photon travels on the inner surface of the pseudoelectron at light speed such that the relativistic electric field at each point of contact with the pseudoelectron is perpendicular to the tangent at that point and the radius R is tangential. The parameter-curve tangent vectors are

$$\begin{matrix}{r}_{u} ( u , v ) = \underline{e} ( \begin{matrix}- r tanh ( u ) sech ( u ) cos ( v ) \\ - r tanh ( u ) sech ( u ) sin ( v ) \\ r - r {sech}^{2} ( u )\end{matrix} ) , & 35.78 ) \\ {r}_{v} ( u , v ) = \underline{e} ( \begin{matrix}- r sech ( u ) cos ( v ) \\ r sech ( u ) sin ( v ) \\ 0\end{matrix} ) & \end{matrix}$$

Such a field is a solution to the sine-Gordon equation and is relativistically invariant. The set of perpendicular field lines extended to infinity form a catenoid that is a minimum surface, one having no mean curvature. The electric fields of the pseudosphere or anti-sphere are in the opposite direction than in the case of a bound electron having spherical geometry. The relativistic electric field is negative in sign and perpendicular to the pseudosphere radius r(u,v) rather than being positive in sign and directed along the spherical central radius. The standard unit normal vector field of the electric field of a pseudoelectron shown in FIG. 8 is

$$\hat{N} ( u , v ) = \vert coth u \vert \underline{e} ( \begin{matrix}( {sech}^{2} ( u ) - 1 ) cos ( v ) \\ ( {sech}^{2} ( u ) - 1 ) sin ( v ) \\ - sech ( u ) tanh u\end{matrix} ) \qquad ( 35.79 )$$

The hyperbolic functions of the photon electric field (Eq. (35.77)) that gives the outward directed force integrates or averages to 2 over one cycle. Thus, for the pseudosphere as a whole the electric force Fₑₗₑ is equivalent to that of a point charge of −e at the origin of a sphere having the pseudosphere radius. The photon is phase locked with the current, and the force due to the mass motion corresponding to the current balances the electric force due to the photon. The centrifugal force that is normal to the surface of the pseudosphere is given by the general equation of force of an object in rotation. The general force in a rotating system is [36]

$${F}_{centrifugal} = {m}_{e} \frac{{d}^{2} R}{{dt}^{2}} + {m}_{e} \frac{d ω}{dt} \times R - 2 {m}_{e} ω \times \frac{dR}{dt} + {m}_{e} ω \times ( ω \times R ) \qquad ( 35.80 )$$

In force balance between the electric and centrifugal forces, the overall frequency ω and radius R are constants such that Eq. (35.80) becomes:

F_{centrifugal}=mₑω×(ω×R) (35.81)

The gravitational mass is zero for a free electron having zero net angular momentum such that it is completely unbounded. Otherwise, it is equivalent to an infinite excited state electron. The scalar angular momentum of a pseudoelectron due to the current is ℏ, and it is constant in force balance. Consider the generator functions of the pseudospherical surface that comprises the pseudoelectron current density function. A tractrix is a curve with the property that the radius hyperbolic R being the segment of the tangent line between the point of tangency and a fixed line called the asymptote is constant, and the revolution of the tractrix about the asymptote by 2π forms a pseudosphere. Both of the electric and centrifugal forces are only normal to the surface of the pseudosphere surface, also corresponding to being only normal to the tangent line. Consider the constancy of the integrated, time averaged angular momentum of ℏ the along all current loops that possess hyperbolic geometry, the constancy of the angular momentum per unit mass of the pseudoelectron, and the effect of the variation of the cylindrical coordinate radii p and the corresponding cross sectional area elements along the current path. The areal velocity as a function of the variable u is equal to one half the angular momentum per unit mass [37]:

$$\frac{dA ( u )}{dt} = \frac{L}{m} = \frac{ℏ}{2 {m}_{e}} \qquad ( 35.82 )$$

The areal velocity as a function of the parameter u is given by the product of the frequency and π times the differential cylindrical coordinate radius squared, the area element of Eq. (35.76):

$$\frac{dA ( u )}{dt} = \frac{{ω}_{u}}{2 π} π {R}^{2} \frac{sech u \vert tanh u \vert du}{2} \qquad ( 35.83 )$$

Using Eqs. (35.82) and (35.83), the position dependent angular velocity ωᵤ is given by [38]

$$\begin{matrix}\frac{{ω}_{u}}{2 π} π {R}^{2} \frac{sech u \vert tanh u \vert du}{2} = \frac{ℏ}{2 {m}_{e}} & ( 35.84 ) \\ {ω}_{u} = \frac{ℏ}{{m}_{e} {R}^{2}} \frac{2}{sech u \vert tanh u \vert du} & ( 35.85 )\end{matrix}$$

Using Eq. (35.81) and (35.85), the centrifugal force F_{centrifugal} (u) becomes

$$\begin{matrix}{F}_{centrifugal} ( u ) = {{m}_{e} ( \frac{ℏ}{{m}_{e} {R}^{2}} \frac{2}{sech u \vert tanh u \vert du} )}^{2} R \frac{2}{sech u \vert tanh u \vert du} \hat{N} \\ = \frac{{ℏ}^{2}}{{m}_{e} {R}^{3}} ( \frac{2}{sech u \vert tanh u \vert du} ) \hat{N}\end{matrix} \qquad ( 35.86 )$$

wherein the radius is corrected for position as a function of the parameter u (Eq. (35.76)). The opposing electric force Fₑₗₑ (u) follows from Eq. (35.77):

$${F}_{ele} ( u ) = \frac{{Ze}^{2}}{4 π {ɛ}_{0} {R}^{2}} \frac{2}{sech u \vert tanh u \vert du} \hat{N} \qquad ( 35.87 )$$

Equating the outward electric force (Eq. (35.87)) to the inward centrifugal force (Eq. (35.86)) gives the pseudoelectron force balance equation:

$$\frac{{ℏ}^{2}}{{m}_{e} {R}^{3}} ( \frac{2}{sech u \vert tanh u \vert du} ) = \frac{{Ze}^{2}}{4 π {ɛ}_{0} {R}^{2}} ( \frac{2}{sech u \vert tanh u \vert du} ) \qquad ( 35.88 )$$

From the force balance equation:

$$R = \frac{4 π {ɛ}_{o} {ℏ}^{2}}{{Ze}^{2} {m}_{e}} = \frac{{a}_{0}}{Z} \qquad ( 35.89 )$$

where the Bohr radius a₀ is given by Eq. (1.256) and Z is the effective charge that may be a rational positive number and corresponds to the energy of the photon that determines the electric field strength of the trapped photon such as that given by Eqs. (5.26-5.28). The electric potential energy given by Eqs. (1.261) and (1.293) is

$$V = \frac{{Ze}^{2}}{4 π {ɛ}_{0} R} = {m}_{e 0} {c}^{2} \frac{{( α Z )}^{2}}{\sqrt{1 - {( α Z )}^{2}}} \qquad ( 35.90 )$$

The relativistic kinetic energy is (Eq. (1.291)):

$$T = {m}_{e 0} {c}^{2} ( \frac{1}{\sqrt{1 - {( \frac{v}{c} )}^{2}}} - 1 ) = {m}_{e 0} {c}^{2} ( \frac{1}{\sqrt{1 - {( α Z )}^{2}}} - 1 ) \qquad ( 35.91 )$$

The binding energy E_{B} is given by the sum of the potential V energy and kinetic energy T, Eq. (1.293) with both contributions positive:

$${E}_{B} = V + T = {m}_{e 0} {c}^{2} \frac{{( α Z )}^{2}}{\sqrt{1 - {( α Z )}^{2}}} + {m}_{e 0} {c}^{2} ( \frac{1}{\sqrt{1 - {( α Z )}^{2}}} - 1 ) = {m}_{e 0} {c}^{2} ( \frac{{( α Z )}^{2} + 1}{\sqrt{1 - {( α Z )}^{2}}} - 1 ) \qquad ( 35.92 )$$

Consider equipotential, minimum energy surfaces with constant positive curvature such as those of spherical H (n=1), excited, and hydrino states. The self-field energy E_{self} is the energy in the electric fields E of the electron alone, Eₑₗₑ, given by (Eqs. (1.263) and (AII.55)):

$${E}_{self} = {E}_{ele} = \frac{1}{2} {ɛ}_{0} {\int }_{0}^{∞} {E}^{2} dv = \frac{1}{2} {m}_{e 0} {c}^{2} \frac{{( α Z )}^{2}}{\sqrt{1 - {( α Z )}^{2}}} \qquad ( 35.93 )$$

The same self-energy considerations apply to spherical autonomous photon-bound electron states in liquid media. In contrast, the pseudoelectron exists in vacuum. Rather than the physical principles of spherical electron bubbles surrounded by species of a liquid, the opposite ones apply in vacuum. Here, each electron does not exist as an interloper in a cage of atoms or molecules wherein their interaction energy is disrupted. The binding energy of the pseudoelectron arises from the negative gravitational potential energy overcoming the positive potential, the kinetic, and the self-energy. The photon fields acting at the electron surface provide the negative central electrostatic force to balance the inward centrifugal force (Eq. (35.88)). The corresponding potential and kinetic energies are given by Eqs. (35.90) and (35.91), respectively. Next consider the self-energy in the pseudoelectron electric fields. The pseudospherical surface area to volume is twice that of the spherical case (Eqs. (35.73) and (35.103)). For a central field photon of a given energy and corresponding field strength (Eqs. (35.77) and (35.87)), the charge density is reduced by a factor of two by Gauss' law. In this case the self-field energy E_{self} comprising the energy in the electric fields E of the electron alone Eₑₗₑ is ¼ that given by Eq. (35.93):

$${E}_{self} ( pseudoelectron ) = \frac{1}{8} {m}_{e 0} {c}^{2} \frac{{( α Z )}^{2}}{\sqrt{1 - {( α Z )}^{2}}} \qquad ( 35.94 )$$

The total energy E_{T} to form the pseudoelectron is the sum of the binding energy E_{B} and self energy E_{self} given by Eqs. (35.92) and (35.94), respectively:

$${E}_{T} = {E}_{B} + {E}_{self} = {m}_{e 0} {c}^{2} ( \frac{{( α Z )}^{2} + 1}{\sqrt{1 - {( α Z )}^{2}}} - 1 ) + \frac{1}{8} {m}_{e 0} {c}^{2} \frac{{( α Z )}^{2}}{\sqrt{1 - {( α Z )}^{2}}} = {m}_{e 0} {c}^{2} ( \frac{\frac{9}{8} {( α Z )}^{2} + 1}{\sqrt{1 - {( α Z )}^{2}}} - 1 ) \qquad ( 35.95 )$$

Using Planck's equation for the relationship of the photon's energy to frequency, the photon energy of state Z is given by Eq. (35.95) is

$${E}_{photon} = ℏ {ω}_{photon} = {E}_{T} = {m}_{e 0} {c}^{2} ( \frac{\frac{9}{8} {( α Z )}^{2} + 1}{\sqrt{1 - {( α Z )}^{2}}} - 1 ) \qquad ( 35.96 )$$

wherein ωₚₕₒₜₒₙ is the frequency of the photon that is trapped by the free electron to form the pseudoelectron state.

Since the electric potential, kinetic, and self-energies are positive, the total energy is positive with the negative binding energy provided by the negative gravitational energy provided by the state of negative curvature. In order for the total energy of the pseudoelectron to be negative and consequently energetically stable, the negative gravitational energy must be at least greater in magnitude than the total energy E_{T} (Eqs. (35.95) and (35.96)). The positive total energy of the pseudoelectron photon depends on Z² (Eqs. (35.95) and (35.96)); whereas, the negative gravitational potential energy (Eq. (35.106)) depends on Z³. The minimum value of photon central field equivalent Z for which the negative gravitational potential energy exceeds the positive total energy of the pseudoelectron photon follows from Eqs. (35.95), (35.96), and (35.106):

$$\begin{matrix}\vert {V}_{G} \vert = {{Z}^{3} ( 1 - {( α Z )}^{2} )}^{- \frac{3}{2}} 1.14 \times {10}^{- 22} J \geq {E}_{T} = {m}_{e 0} {c}^{2} ( \frac{\frac{9}{8} {( α Z )}^{2} + 1}{\sqrt{1 - {( α Z )}^{2}}} - 1 ) & ( 35.97 ) \\ Z \geq {( \frac{{m}_{e 0} {c}^{2} ( \frac{\frac{9}{8} {( α Z )}^{2} + 1}{\sqrt{1 - {( α Z )}^{2}}} - 1 ) {( 1 - {( α Z )}^{2} )}^{\frac{3}{2}}}{1.14 \times {10}^{- 22} J} )}^{\frac{1}{3}} & \\ Z \geq 137 & \end{matrix}$$

wherein. (35.97) was solved reiteratively. Thus, the minimum energy photon to excite a stable pseudoelectron state is given Eqs. (35.96) and (35.97) is

$${E}_{photon} = {E}_{T} = {m}_{e 0} {c}^{2} ( \frac{\frac{9}{8} {( α Z )}^{2} + 1}{\sqrt{1 - {( α Z )}^{2}}} - 1 ) = {m}_{e 0} {c}^{2} ( \frac{\frac{9}{8} {( α 137 )}^{2} + 1}{\sqrt{1 - {( α 137 )}^{2}}} - 1 ) = 7.51 \times {10}^{- 12} J = 46.8 \times {10}^{6} eV \qquad ( 35.98 )$$

The electric potential energy given by Eqs. (35.90) and (35.97) is

$$V = {m}_{e 0} {c}^{2} \frac{{( α Z )}^{2}}{\sqrt{1 - {( α Z )}^{2}}} = {m}_{e 0} {c}^{2} \frac{{( α 137 )}^{2}}{\sqrt{1 - {( α 137 )}^{2}}} = 3.57 \times {10}^{- 12} J = 22.3 \times {10}^{6} eV \qquad ( 35.99 )$$

The kinetic energy T given by Eqs. (35.91) and (35.97) is

$$T = {m}_{e 0} {c}^{2} ( \frac{1}{\sqrt{1 - {( α Z )}^{2}}} - 1 ) = {m}_{e 0} {c}^{2} ( \frac{1}{\sqrt{1 - {( α137 )}^{2}}} - 1 ) = 3.49 \times {10}^{- 12} J = 21.8 \times {10}^{6} eV \qquad ( 35.100 )$$

The binding energy E_{B} given by Eqs. (35.92) and (35.97) is

$${E}_{B} = {m}_{e 0} {c}^{2} ( \frac{{( α Z )}^{2} + 1}{\sqrt{1 - {( α Z )}^{2}}} - 1 ) = {m}_{e 0} {c}^{2} ( \frac{{( α 137 )}^{2} + 1}{\sqrt{1 - {( α 137 )}^{2}}} - 1 ) = 7.06 \times {10}^{12} J = 44.1 \times {10}^{6} eV \qquad ( 35.101 )$$

The self-field energy E_{self} comprising given by Eqs. (35.94) and Eq. (35.97) is

$${E}_{self} = \frac{1}{8} {m}_{e 0} {c}^{2} \frac{{( α Z )}^{2}}{\sqrt{1 - {( α Z )}^{2}}} = \frac{1}{8} {m}_{e 0} {c}^{2} \frac{{( α 137 )}^{2}}{\sqrt{1 - {( α 137 )}^{2}}} = 4.46 \times {10}^{- 13} J = 2.78 \times {10}^{6} eV \qquad ( 35.102 )$$

Pseudoelectron production may be achieved by irradiating electrons having zero gravitational mass m_{g} with gamma rays of energy of at least 46.8×10⁶ eV wherein the incident gamma ray photons excite the electrons to pseudoelectrons. The energies of the pseudoelectrons may be increased to relativistic energies to increase the fifth force effect (Eq. (35.107)). A fifth force device to provide lift comprises a source of pseudoelectrons comprising a source of free electrons having m_{g}=0, a source of γ-ray photons to excite the pseudoelectron transitions, and a means to transduce the upward force on the pseudoelectrons to a device or object which is desired to be lifted or levitated. The transducer may comprise electrostatically charged plates that are repelled by the gravitationally upward forced pseudoelectrons.

### Fifth Force Energies of Pseudoelectron States

The curvature K of a pseudoelectron is determined by its radius R. The curvature is given by Eq. (35.8). The force balance of the centrifugal and central forces due to the pseudospherical photon determine the radius R. As Z increases, R decreases, and curvature K increases. The curvature of the pseudoelectron is negative, the space is negatively curved or hyperbolic, and the force of gravity is negative and dependent on the degree of negative curvature of the pseudoelectron. As shown in the Gravity section (Eq. (32.35)), the derivation of the relativistic correction factor of spacetime was based on the constant maximum velocity of light and a finite positive Newtonian gravitational velocity v_{g} of the particle. The production of a particle requires that the velocity of the particle is equivalent to the Newtonian gravitational escape velocity, v_{g}, of the antiparticle given by Eq. (35.11). From Eq. (35.22) and Eqs. (35.18-35.19), the eccentricity is one and the particle production trajectory is a parabola relative to the center of mass of the antiparticle. The right-hand side of Eq. (32.43) represents the correction to the laboratory coordinate metric for time corresponding to the relativistic correction of spacetime by the particle production event. Consider a Newtonian gravitational radius, r_{g}, of each orbitsphere of the particle production event, each of mass m₀ given by Eq. (35.12). The substitution of each of Eq. (35.11) and Eq. (35.12) into the Schwarzschild metric Eq. (35.2) gives Eqs. (35.13) and (35.14), respectively. The solutions for the Schwarzschild metric exist wherein the relativistic correction to the gravitational velocity v_{g} and the gravitational radius r_{g} are of the opposite sign (i.e. negative). In these cases, the Schwarzschild metric (Eq. (35.2)) is given by Eqs. (35.13) and (35.14), respectively. The metric given by Eqs. (35.13-35.14) corresponds to positive curvature. The metric given by Eqs. (35.15-35.16) corresponds to negative curvature.

The Universe is a four-dimensional hyperspace of constant positive curvature at each r-sphere. The coordinates are spherical, and the space can be described as a series of spheres each of constant radius r whose centers coincide at the origin. The existence of the mass m_{U} of a gravitating body causes the area of the spheres to be less than 4πr² and causes the clock of each r-sphere to run so that it is no longer observed from other r-spheres to be at the same rate. That is, clocks slow down in a gravitational field [3]. The Schwarzschild metric given by Eq. (32.38) is the general form of the metric that allows for these effects. For a particle in positive curvature the radius of curvature and its area offset each other for all radii such as those of excited states. This is not the case for a particle of negative curvature corresponding to hyperbolic space. The gravitational velocity v_{g} and the gravitational radius r_{g} of the pseudoelectron in Eqs. (35.15-35.16), may be determined by considering the differential effect on the spherical r-spheres due to the inverse spherical mass density geometry of a pseudoelectron wherein its mass in negative curvature produces negatively curved spacetime. Consequently, the pseudoelectron is repelled from positive curved spacetime created by an ordinary gravitating body.

The volume V of the pseudoelectron is one half that of the electron orbitsphere of the same radius R:

V=2/3πR³ (35.103)

At the fundamental scale of particles, the gravitation force arises from the spherical volumetric contraction of spacetime by production of a fundamental particle of positive curvature. Conversely, the formation of a pseudoelectron causes spacetime to be warped into a hyperbolic spacetime contribution corresponding to the pseudoelectron mass in negative curvature. The corresponding antigravitational force is called the fifth force. The gravitational mass of the electron becomes negative, but the magnitude of the mass must be corrected for the greater effect of hyperbolic over spherical geometry. The spacetime integral over the three-space involving the radii between R-spheres is given by the differential in volumes defined by the R-spheres having the radii of the gravitating particles of the bound electron relative to the pseudoelectron. The relative differential spacetime volume change is equivalent to that due to forming a negatively curved pseudoelectron from the positively curved hydrino state having the same radius and a central field of the same magnitude. From Eqs. (35.73) and (35.103), the volume of a spherical electron and a pseudospherical electron having the same radius within its spacetime geometry differ by a factor of two. Moreover, the differential spherical to pseudospherical volume depends on R⁻³ which in turn depends on Z³, and the radius must be relativistically corrected after Eqs. (35.90) and (35.91). Thus, the fifth force electron mass is given by

$${m}_{e pseudoelectron} = - 2 {( \frac{z}{{( 1 - {( α Z )}^{2} )}^{\frac{1}{2}}} )}^{3} {m}_{e} = - 2 {{Z}^{3} ( 1 - {( α Z )}^{2} )}^{- \frac{3}{2}} {m}_{e} \qquad ( 35.104 )$$

As in the case with a positive gravitating body, the pseudoelectron translational kinetic energy may be increased and thereby the translational relativistic mass may be increased by using an accelerator after the formation of the pseudoelectron. Using Eq. (33.14), the translational relativistic fifth force pseudoelectron mass is given by

$${m}_{e pseudoelectron} = - 2 {{Z}^{3} ( 1 - {( α Z )}^{2} )}^{- \frac{3}{2}} {{m}_{e} ( 1 - {( \frac{v}{c} )}^{2} )}^{- \frac{1}{2}} \qquad ( 35.105 )$$

The corresponding gravitational energy V_{G} is given by

$$\begin{matrix}{V}_{B} = \frac{{GMm}_{e pseudoelectron}}{r} \\ = - {{Z}^{3} ( 1 - {( α Z )}^{2} )}^{- \frac{3}{2}} {( 1 - {( \frac{v}{c} )}^{2} )}^{- \frac{1}{2}} \frac{\begin{matrix}2 ( 6.67 \times {10}^{- 11} N \cdot {m}^{2} \text{/} {kg}^{2} ) \\ ( 5.98 \times {10}^{24} kg ) ( 9.109 \times {10}^{- 31} kg )\end{matrix}}{( 6.37 \times {10}^{6} m )} \\ = - {{Z}^{3} ( 1 - {( α Z )}^{2} )}^{- \frac{3}{2}} {( 1 - {( \frac{v}{c} )}^{2} )}^{- \frac{1}{2}} 1.14 \times {10}^{- 22} J \\ = - {{Z}^{3} ( 1 - {( α Z )}^{2} )}^{- \frac{3}{2}} {( 1 - {( \frac{v}{c} )}^{2} )}^{- \frac{1}{2}} 7.12 \times {10}^{- 4} eV\end{matrix} \qquad ( 35.106 )$$

The fifth force energy may be amplified by increasing the pseudoelectron mass with velocity. Consider the electron mass energy due to translational velocity given by Eq. (34.13), and as a comparison, the velocity dependency of the fifth force energy (Eq. (35.106)). For an exemplary case having v=0.999c , the gravitation potential of Eq. (35.106) and the corresponding fifth force energy increased 22 fold:

$${V}_{G} = {{Z}^{3} ( 1 - {( α Z )}^{2} )}^{- \frac{3}{2}} {( 1 - {( \frac{0.999 c}{c} )}^{2} )}^{- \frac{1}{2}} 1.14 \times {10}^{- 22} J = {{Z}^{3} ( 1 - {( α Z )}^{2} )}^{- \frac{3}{2}} 2.55 \times {10}^{- 21} J = {{Z}^{3} ( 1 - {( α Z )}^{2} )}^{- \frac{3}{2}} 1.59 \times {10}^{- 2} eV \qquad ( 35.107 )$$

As the mass energy becomes large compared to the rest mass energy, the fifth force energy increases rapidly with the pseudoelectron mass energy increase. Moreover, as shown by Eq. (35.97) the negative gravitational potential dominates the total energy as Z corresponding to the photon energy becomes large. Thus, the combination of using high-energy photons to produce pseudoelectrons having the corresponding fifth force energy of Eq. (35.106) and further accelerating the pseudoelectrons to high velocity can yield a maximum combined efficiency of excitation energy to fifth force energy close to unity. This result is extraordinary given the fifth force capability of thousands of times more energy per mass than rockets using propellants and the elimination of ejecting mass as the propulsion mechanism wherein the fuel mass consumed to achieve orbit is typically about ten times the payload mass due to the logarithmic dependency on mass of the rocket equation:

$$v = {v}_{0} + V ln \frac{{m}_{0}}{m} \qquad ( 35.108 )$$

where v is the velocity of the rocket at any time, v₀ is the initial velocity of the rocket, m₀ is the initial mass of the rocket plus unburned fuel, m is the mass at any time, and V is the speed of the ejected fuel relative to the rocket.

### Fifth Force Propulsion Device

Lift can be transferred from pseudoelectrons generated by an F² device to an object to be lifted such as a craft. The lifting force may be transferred by directing the negatively charged, Earth-repelled pseudoelectrons through a first positively charged grid electrode to a counter, negatively charged electrode of a capacitor. The electrical repulsion between the pseudoelectrons and the negative electrode will cause the fifth force of the pseudoelectrons to be transferred to the negative electrode and any object to which the capacitor is rigidly attached such as a craft

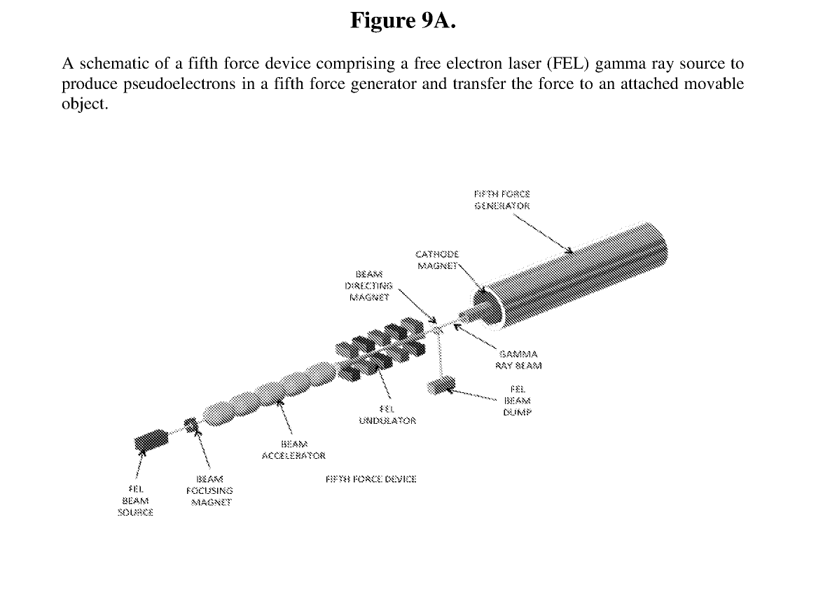

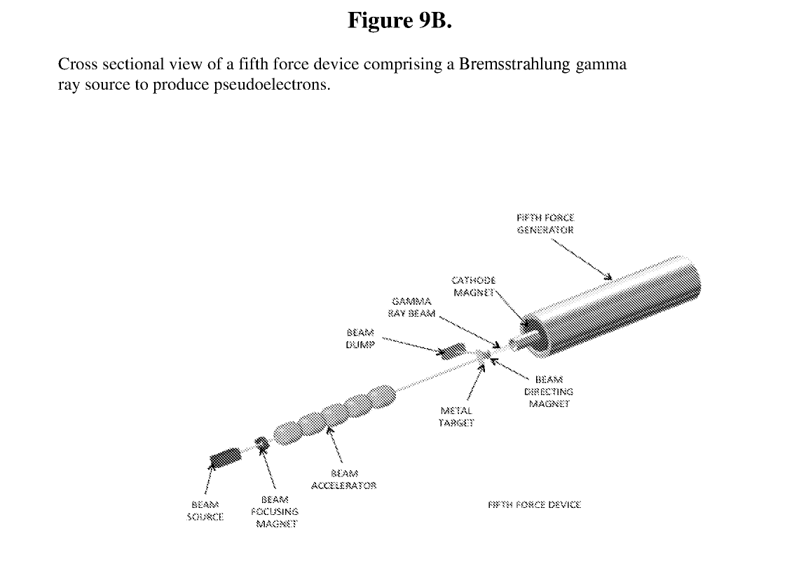

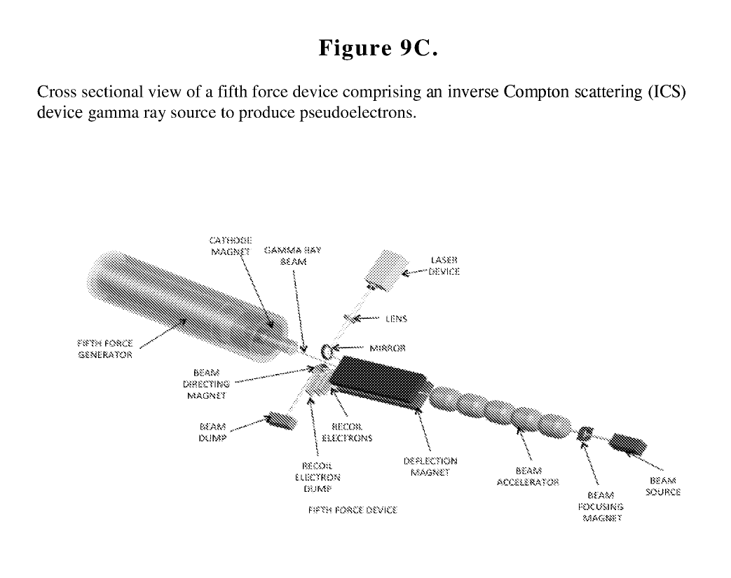

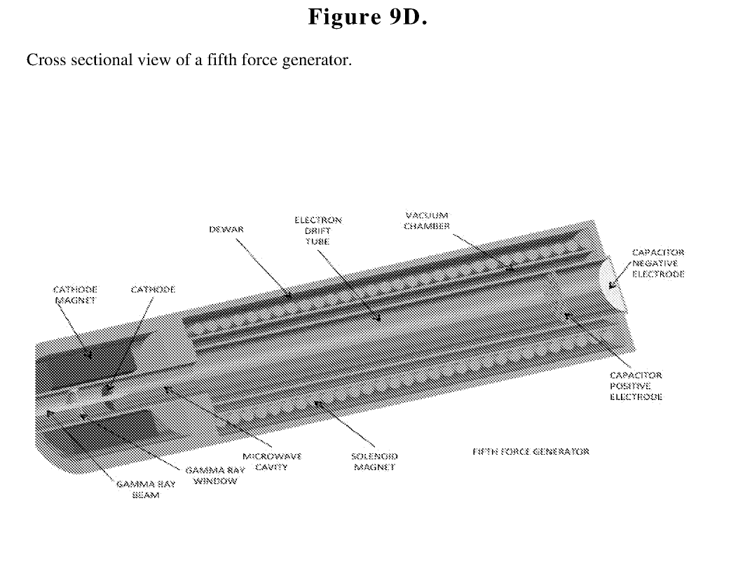

Specifically, the fifth-force device shown in FIGS. 9A-9D comprises a source of free electrons, a plurality of electron isolation tubes or drift tubes, a source of gamma rays, and a force converter. The electron isolation or drift tubes may comprise a guide path for free electrons in the substantial absence of external electric and magnetic potential energy gradients along the Earth's gravitational field lines. The drift tube may comprise a thermally insulated, cryogenically cooled, highly conductive metal tube having a highly uniform inner surface. A very weak uniform axial field may be applied by running a low DC current through the drift tube. A weak magnetic field may be applied axially along the drift tube by a solenoidal super-conducting magnet circumferential to the drift tube. The free electrons may be from a source such as an electron-emitting cathode wherein a slight positive bias may be applied relative to the drift tube near the cathode to increase the yield of slow electrons. A population of slow electrons may each have a zero or near zero net magnetic moment be due to the production of electrons having the spin and orbital magnetic monuments essentially canceling. The cancellation may be achieved by interaction of the electron spin and orbital angular momentum. The cancellation may be achieved by forming the electrons in a high magnetic field. Electrons with the desired near cancellation of the magnetic moments may be separated magnetically before entering the drift tube. The magnet may produced a divergent magnetic field at the cathode region that traps electrons having a net magnetic moment while permitting electrons having essentially no magnetic moment to drift to into the drift tube wherein they are irradiated with gamma rays of sufficient energy and polarization to form pseudoelectrons. The injected electrons may be in the free ground state. The fifth-force device may comprise a source of microwaves to cause the free electrons of a beam of free electrons to undergo a transition to the ground state wherein the spin and orbital magnetic monuments essentially cancel.

In other embodiments, the F² device comprises a plasma source of free electrons. The plasma source may comprise a vessel or cavity, a source of plasma gas, a plasma maintenance system such as electrodes or at least one antennae and a source of input power to the gas to maintain the plasma such as a high voltage DC or AC power source that may be applied to the electrodes or an RF or microwave power source to be applied to the at least one antennae, gas sensors and controls, and plasma sensors and controls. The gas control system may comprise a gas supply such as a tank, valves, flow regulators, and at least one pump. The plasma gas may comprise at least one of air, a noble gas, nitrogen, hydrogen, carbon dioxide, an inert gas, and other plasma gases known to those skilled in the art. The source of free electrons may comprise at least one of a source of electric and magnetic fields. The free electrons may be selected form the plasma by at least one of electric and magnetic fields. The free electrons may be guided into at least one tube for irradiation by gamma rays to form pseudoelectrons. The free electrons may be guided into at least one chamber to be converted to free electrons having essentially no net magnetic moment wherein additionally the external fields may be substantially removed. The converted free electrons may be irradiated by gamma rays to form pseudoelectrons. The F² device may further comprise a system to maintain a very low gas pressure in at least one region of free electron propagation, pseudoelectron formation, pseudoelectron propagation. The low gas pressure may be maintained by differential pumping. The differential pumping system may comprise at least one aperture for flow of free electrons such as a pin-hole aperture, and at least one gas pump. The system may further comprise gas pressure sensors and controls. In another embodiment, the source of free electrons may comprise an electron beam wherein the electron beams systems comprise those known in the art. The source of free electrons may comprise at least one laser and at least one ionization target wherein free electrons are ionized from the target by the laser. The source of free electrons may comprise at least one of thermionic, Schottky field emission, cold field emission, and photoelectron sources such as those known in the art. The source may comprise an electron gun.

The ground state free electrons having zero gravitational mass are incident photons such as gamma rays wherein the absorption of the gamma rays of at least the energy for pseudoelectron production (Eqs. (35.96) and (35.98)) causes the electrons to form pseudoelectrons having a negative gravitational mass. Exemplary sources of gamma ray are a Bremsstrahlung source, a synchrotron source, an inverse Compton scattering (ICS) device comprising a laser for at least one of providing photons for ICS and to provide a laser-wakefield-accelerated relativistic electron beam that may alternatively be produced by an accelerator, a free electron laser, and a radioactive material that emits gamma rays of energy sufficient to form pseudoelectrons. The Bremsstrahlung source may comprise an electron beam accelerator such as a betatron a linac, a synchrotron, a high voltage source such as a Marx generator, a van der Graaf generator, a laser wakefield accelerator and another electron accelerator known to those skilled in the art. The photon sources shown in FIGS. 35.9A-D may be tuned to produce γ-rays that excite the electrons to form pseudoelectrons. Compton scattered and nuclear sources are convenient to provide linearly polarized γ-rays. Alternatively, the F² device may comprise a polarizer that may be used. Energy of the beam not converted into pseudoelectrons may be recovered using a beam recovery and transport system. The pseudoelectrons drift or are accelerated into a converter section of the guide path wherein the upward fifth-force is transferred to the converter that converts the pseudoelectrons fifth-force into lift of a craft rigidly attached to the converter. The converter may be a capacitor. The capacitor may comprise an input grid electrode wherein the pseudoelectrons traverse the grid and experience an electric field from a field source confined to the inter-electrode region wherein the pseudoelectrons push up on the top negatively charged electrode.

In an embodiment, the F² device comprises a source of high kinetic energy second bodies to impact free electrons such as ones having about zero spin angular momentum to form pseudoelectrons. The source of the high kinetic energy second bodies may be one known by those skilled in the art. The second body may be selected to have a high mass such that the corresponding velocity at high energy is lower. High mass second bodies may also have a larger interaction cross section. An exemplary second body is a xenon ion or atom wherein the ions may form high-energy neutrals by electron neutralization. The ion neutralization may occur when incident the free electrons or a source of electrons. The ions may be accelerated to high energy using a particle accelerator such as an oscillating field accelerator, an electrostatic accelerator, a linear accelerator, a circular accelerator, a cyclotron, a synchrotron, a laser pulse accelerator, a laser wake field accelerator, a laser ion accelerator, a laser target normal sheath accelerator, a laser radiation pressure accelerator, or other accelerator known by those skilled in the art. Another exemplary second body and source are protons and a proton beam source, respectively.

In an embodiment, high kinetic energy of second bodies such as at least one of high kinetic energy particles, atoms, ions, protons, neutrons, alpha particles, and electrons are incident free electrons to excite the formation of pseudoelectrons. The mechanism may regard that of the Franck-Hertz experiment. The kinetic energy of the second body may be transferred to the free electron by an inelastic collision to cause the bombarded free electron to form a pseudoelectron. The high kinetic energy of the incident second body may be at least that which results in the formation of a pseudoelectron. The kinetic energy of the second body may be at least about 50 MeV. In the Franck-Hertz experiment, an energetic electron bombards an atom to cause an atomic excited state transition. In an exemplary embodiment, the excitation of a free electron to form a pseudoelectron may comprise an inverse Franck-Hertz mechanism wherein the high kinetic energy of an incident atom is transferred to the bombarded electron to form a pseudoelectron.

Extraordinarily high power laser pluses can cause pair production and even muon production. In another embodiment, high power laser pulses such as pulses in at least one energy range of about 1×10³ W to 1×10²⁵ W, 1×10⁵ W to 1×10²⁴ W, and 1×10⁸ W to 1×10²² W that may correspond to high power density such as at least one power density in the range of about 1×10⁵ W/cm² to 1×10²⁵ W/cm², 1×10⁸ W/cm² to 1×10²⁴ W/cm², and 1×10¹⁰ W/cm² to 1×10²³ W/cm² can produce gamma rays in solid targets such as plastic ones. In an embodiment, a gamma ray beam may be formed by irradiating a shaped carbon target with a strong laser pulse to form high-energy plasma. In an exemplary embodiment, infrared lasers pulses of 5×10²² W corresponding to 5×10²² W/cm² are fired at a carbon-rich plastic target. The gamma ray beam may be made incident free electrons to form pseudoelectrons.

In an embodiment, multiple photon events at enormous power density can cause pseudoelectron production. In an embodiment, free electrons are irradiated with a high power laser to form pseudoelectrons. In an embodiment, pseudoelectrons are formed by free electrons such as those of zero curvature, each undergoing multiple photon absorption. The F² device may comprise a high-power laser that supplies the multiple photons. The summation of the energies of the photons absorbed by each electron that forms a pseudoelectron may be above the threshold for pseudoelectron formation. The laser wavelength may be in the spectral region from infrared to gamma ray. The laser may comprise a free electron laser such as an X-ray free electron laser (XFEL). In an embodiment, the F² device comprises a hydrino reactor or SunCell to produce a high concentration of photons. The plurality of photons incident each free electron for multi-photon absorption to form a pseudoelectron may be supplied by the hydrino reactor.

In an embodiment, the capacitor having an applied potential may be replaced by a pseudoelectron target that has no applied voltage. The target may comprise a grid, plate or cup such as a faraday cup that receives the incident pseudoelectrons wherein upward pseudoelectron force is transferred to the grid, plate or cup. In an embodiment, the capacitor, grid, plate, or cup comprising a pseudoelectron deflector is tilted relative to being transverse to the gravitational field axis. The tilted pseudoelectron deflector receives the incident pseudoelectrons wherein upward pseudoelectron lift is transferred to the tilted deflector such that at least one of vertical and transverse components of force are transferred to the deflector and thereby to an attached object such a as craft. The recoiling pseudoelectrons may be collected in an electron trap such as a faraday cup and re-circulated. The deflector and electron trap may be cooled by means known by those skilled in the art. The target such as the capacitor, grid, plate, cup, or deflector may accumulate electrons to become charged to more effective couple at least one of the vertical and transverse forces to the target. In an embodiment, the fifth force generator or device may be tilted relative to being transverse to the gravitational field axis. The tilted pseudoelectron fifth force generator or device receives the incident pseudoelectrons wherein upward pseudoelectron lift is transferred to the tilted fifth force generator or device such that at least one of vertical and transverse components of force are transferred to the fifth force generator or device and thereby to an attached object such a as craft. The transverse component of force may be controlled to assist in causing a transverse trajectory of the craft facilitated by tilting the spinning craft as given in the Mechanisms of Craft Translational Motion section, the Mechanics section, and the Analytical Mechanical Analysis of the Fifth Force Craft Wobble Motion section. A plurality of at least one of fifth force generators with tiltable deflectors, tiltable fifth force generators, and tiltable fifth force devices may be used to control vertical and transverse components of propulsion wherein the fifth force device further comprises a controller to control the components of the propulsion and motion of the object or craft.

A simple device for space maneuvering applications such as satellite positioning is a tapered microwave cavity optionally comprising a weak magnetic field, possibly the Earth's magnetic field, that maintains some microwave plasma in the magnetic field to produce electrons with about zero net magnetic moment. The Earth's cosmic ray flux at 1 GeV is

$$\frac{{10}^{4}}{s {m}^{2}} .$$

These rays are converted to some high-energy gamma rays due to collisions in the atmosphere, and further γ-rays arise from interaction with the plasma vessel wall. High-energy γ-rays irradiate these electrons in lieu of a γ-ray source and form pseudoelectrons. The upward lift on pseudoelectrons is incident at an angle due to the taper that results in a transverse as well as a vertical component of force such that a component of force is directed towards the narrow end of the taper to permit maneuvering along two axes. Each 1 GeV event can produce a force of 10 μN over a distance of about 16 μm.

In an embodiment, electrons are accelerated to relativistic energies using a so called photon collider comprising counter-propagating, focused, ultra-short laser pulses and the diagnostic means to accurately achieve spatial and temporal overlap of these pulses. In an embodiment, electrons are subjected to light intensity exceeding 10¹⁸W/cm² that represents a relativistic threshold in the near infrared wavelength regime. Electrons that are subjected to light intensities exceeding this value oscillate with relativistic velocities to cause at least one of laser particle acceleration and laser-generated high-energy photons. In another embodiment, the electrons may be accelerated by laser acceleration or laser wake field acceleration. At least one of the electron and photon energies that are achieved is at or above the threshold to form pseudoelectrons. In an embodiment, the electron beam and photon beam intersect or collide to achieve inverse Compton scattering to increase the photon energy to at or above the threshold to form pseudoelectrons. In an embodiment, the gamma ray source may comprise at least one of a Bremsstrahlung source, a synchrotron source, a free electron laser, a free-electron laser based Compton backscattering gamma-ray source, an inverse Compton scattering source, and a radioactive material that emits gamma rays of energy sufficient to form pseudoelectrons.

In an embodiment, the F² device comprises a source of free electrons, a plurality of electron isolation tubes or drift tubes, a source of gamma rays, and a force converter. The electron isolation or drift tubes may comprise a guide path for free electrons in the substantial absence of external electric or magnetic fields. The elimination of the fields may such to eliminate the corresponding forces along the Earth's gravitational field. The drift tube may comprise a metal tube. The metal tube may be cryogenically cooled. At least one of the electric and magnetic potential energy gradients along the gravitational field axis may be reduced to at least one range of below 10⁻¹⁵ eV/m, below 10⁻¹⁴ eV/m, below 10⁻¹³ eV/m, below 10⁻¹² eV/m, below 10⁻¹¹ eV/m, below 10⁻¹¹ eV/m, below 10⁻¹⁰ eV/m, below 10⁻⁹ eV/m, below 10⁻⁸ eV/m, below 10⁻⁷ eV/m, below 10⁻⁶ eV/m, and below 10⁻⁵ eV/m. Each drift tube may comprise a tube comprised of a highly conductive metal such as copper or silver. The tube may have at least one of a uniform inner surface with surface variations of at least one range of less than 10⁻⁸ m, less than 10⁻⁷ m, less than 10⁻⁶ m, less than 10⁻⁵ m, less than 10⁻⁴ m, and less than 10⁻³ m. The drift tube may be thermal insulated. The drift tube may be cryogenically cooled. The drift tube may be surrounded by a source of a magnetic field. The magnetic field may be axial to the drift tube. The magnetic field may be provided by a solenoidal magnet such as an electromagnet or a superconducting magnetic circumferential to the drift tube. The super-conducting magnet may be cryogenically cooled. The electrons may each have a zero or near zero net magnetic moment. The zero or near zero net magnetic moment be due to the production of electrons having the spin and orbital magnetic monuments essentially canceling. The cancellation may be achieved by interaction of the electron spin and orbital angular momentum. The cancellation may be achieved by forming the electrons in a high magnetic field. The magnetic field may be in at least one range of about 10⁻⁴ T to 100 T, 10⁻³ T to 10 T, and 1 T to 10 T. A cathode may emit the electrons. Electrons with the desired near cancellation of the magnetic moments may be separated magnetically before entering the drift tube. The injected electrons may be in the free ground state. In an embodiment, the F² device comprises a source of microwaves to cause the free electrons of a beam of free electrons to undergo a transition to the ground state wherein the spin and orbital magnetic monuments essentially cancel. The ground state electrons may be incident photons such as gamma rays that cause the electrons to form pseudoelectrons.

In an embodiment, at least one of the electron magnetic moment cancellation and the isolation cause the free electrons to have zero gravitational mass. The isolation may be achieved in the drift tubes. The drift tubes may be incident free electrons in an input section. Gamma rays from the source of gamma rays may be caused to travel along the axis of the free electrons and be incident on the free electrons having zero gravitational mass. The gamma rays may be of sufficient energy to cause electrons to transition to pseudoelectron states. In an embodiment, the energy of the photon that excites a pseudoelectron transition is acquired at least partially from the inverse Compton effect. The photons undergoing the inverse Compton effect may be from a high-power laser. The pseudoelectrons may drift into a converter section of the guide path wherein the upward F² force is transferred to the converter that converts the pseudoelectron F² force into lift of a craft rigidly attached to the converter. In an embodiment, the pseudoelectrons may be at least one of accelerated vertically to increase the relativistic velocity and accelerated horizontally to apply a transverse component of momentum. The electron acceleration may be achieved with an electron accelerator. The converter may be a capacitor. The capacitor may comprise an input grid electrode wherein the pseudoelectrons traverse the grid and experience an electric field confined to the inter-electrode region.

The F² device may comprise a SunCell as a source of low energy electrons to form pseudoelectrons. A large population of electrons at low energy may be formed by the reaction of a catalyst such as HOH capable of accepting energy of about an integer multiple of 27.2 eV from atomic hydrogen to form hydrinos. The catalyst may resonantly and nonradiatively accept the integer multiple of 27.2 eV of energy from atomic hydrogen to become ionized with essentially zero kinetic energy. The SunCell may comprise five fundamental systems: (i) a start-up inductively coupled heater to first melt silver or silver-copper alloy and optionally an electrode electromagnetic pump to initially direct the ignition plasma stream; (ii) an injection system comprising an electromagnetic pump to inject molten silver or molten silver-copper alloy and a gas injector to inject water vapor and optionally hydrogen gas; (iii) an ignition system to produce a low-voltage, high current flow across a pair of electrodes into which the molten metal and gases are injected to form a brilliant light-emitting plasma; (iv) a light to electricity converter comprising so-called concentrator photovoltaic cells that operate at a high light intensity such as over one thousand Suns; and (v) a fuel recovery and a thermal management system that causes the molten metal to return to the injection system following ignition. The SunCell systems and methods and hydrino solid fuels reactants, systems, and methods such as those to form hydrinos, plasmas, and free electrons may comprise those of the present disclosure or in prior US Patent Applications such as Hydrogen Catalyst Reactor, PCT/U.S. Ser. No. 08/61455, filed PCT Apr. 24, 2008; Heterogeneous Hydrogen Catalyst Reactor, PCT/U.S. Ser. No. 09/052072, filed PCT Jul. 29, 2009; Heterogeneous Hydrogen Catalyst Power System, PCT/U.S. Ser. No. 10/27828, PCT filed Mar. 18, 2010; Electrochemical Hydrogen Catalyst Power System, PCT/U.S. Ser. No. 11/28889, filed PCT Mar. 17, 2011; H₂O-Based Electrochemical Hydrogen-Catalyst Power System, PCT/US12/31369 filed Mar. 30, 2012; CIHT Power System, PCT/U.S. Ser. No. 13/041938 filed May 21, 2013; Power Generation Systems and Methods Regarding Same, PCT/IB2014/058177 filed PCT Jan. 10, 2014; Photovoltaic Power Generation Systems and Methods Regarding Same, PCT/U.S. Ser. No. 14/32584 filed PCT Apr. 1, 2014; Electrical Power Generation Systems and Methods Regarding Same, PCT/US2015/033165 filed PCT May 29, 2015; Ultraviolet Electrical Generation System Methods Regarding Same, PCT/US2015/065826 filed PCT 12//2015, and Thermophotovoltaic Electrical Power Generator, PCT/US2016/12620 filed PCT 1//2016 (“Mills Prior Applications”), the contents of which are herein incorporated by reference in their entirety. The SunCell may provide a source of electrical power to power the F² device.

The source of gamma rays that are incident free electrons to form pseudoelectron may comprise the hydrino reaction with a catalyst that catalyzes transition to at least one state H(1/p) wherein p is large. The proton and electron of a hydrino atom comprising a high p state may annihilate to photons and electron neutrinos as given in the New “Ground” State section. To conserve spin (angular momentum) the reaction is

$${\overline{v}}_{e} + {}^{1} H [ \frac{{a}_{H}}{p} ) \to γ + {v}_{e} \qquad ( 32.173 )$$

where vₑ is the electron neutrino.

### Fifth Force Performance

Consider the case that the fifth force energy of the pseudoelectron is 4.7×10⁷ eV (7.5×10⁻¹² J) as given by Eqs. (35.98) and (35.106) and the upward pseudoelectron current is 200 A . The maximum power transferred to the device P_{FF} is

$${P}_{FF} = ( \frac{200 C}{s} ) ( \frac{1 pseudoelectron}{1.6 \times {10}^{- 19} C} ) ( \frac{7.5 \times {10}^{- 12} J}{pseudoelectron} ) = 9.4 GW \qquad ( 35.109 )$$

The power dissipated against gravity P_{G} is given by

P_{G}=m_{c}gv_{c} (35.110)

where m_{c} is the mass of the craft, g is the acceleration of gravity, v_{c} is the velocity of the craft. In the case of a 10⁶ kg craft, 9.4 GW of power provided by Eq. (35.109) sustains a steady lifting velocity of 9400 m/s. Thus, significant lift is possible using pseudoelectrons. In the case of a 10⁶ kg craft, F_{g}, the gravitational force is

$${F}_{g} = {m}_{c} g = ( {10}^{6} kg ) ( 9.8 \frac{m}{{sec}^{2}} ) = 9.8 \times {10}^{6} N \qquad ( 35.111 )$$

where m_{c} is the mass of the craft and g is the standard gravitational acceleration. The lifting force may be determined from the gradient of the energy which is approximately the energy dissipated divided by the vertical (relative to the Earth) distance over which it is dissipated. The electric field of the capacitor may be adjusted to control the fifth force provided by the pseudoelectrons. For example, the electric field of the capacitor may be increased such that the levitating force overcomes the gravitational force. The electric field of the capacitor, E_{cap}, may be constant and given by the capacitor voltage, V_{cap}, divided by the distance between the capacitor plates, d, of a parallel plate capacitor.

$${E}_{cap} = \frac{{V}_{cap}}{d} \qquad ( 35.112 )$$

In the case that V_{cap} is 4.7×10⁷ V and d is 1 m, the electric field is

$${E}_{cap} = \frac{4.7 \times {10}^{7} V}{m} \qquad ( 35.112 )$$

The force of the electric field of the capacitor on a pseudoelectron, Fₑₗₑ, is the electric field, E_{cap}, times the fundamental charge

$$\begin{matrix}{F}_{ele} = e {E}_{cap} \\ = ( 1.6 \times {10}^{- 19} C ) ( 4.7 \times {10}^{7} \frac{V}{m} ) = 7.5 \times {10}^{- 12 } N\end{matrix} \qquad ( 35.114 )$$

The distance traveled away from the Earth, Δr_{z}, by a pseudoelectron having energy of 4.7×10⁷ eV (7.5×10⁻¹² J) is given by the energy divided by the electric field force Fₑₗₑ

$$Δ {r}_{z} = \frac{E}{{F}_{ele}} = \frac{7.5 \times {10}^{- 12} J}{7.5 \times {10}^{- 12} N} = 1 m \qquad ( 35.115 )$$

The maximum fifth force power P_{FFC} that can be transduced by the capacitors is given by the product of the 200 A current of pseudoelectrons times the capacitor force give by Eq. (35.114):

$${P}_{FFC} = ( \frac{200 C}{s} ) ( \frac{1 pseudoelectron}{1.6 \times {10}^{- 19} C} ) ( 7.5 \times {10}^{- 12} N ) = 9.4 GW \qquad ( 35.116 )$$

wherein the power P_{FFC} acts over the distance Δr_{z}=1 m . Thus, this example of a fifth-force device may provide a levitating force that is capable of overcoming the gravitational force on the craft to achieve a maximum vertical velocity of 9400 m/s as given by Eq. (35.111). The pseudoelectron current and the electric field of the capacitor may be adjusted to control the vertical acceleration and velocity.

### Mechanisms of Craft Translational Motion

A fifth-force device can cause radial motion relative to the gravitating body such as the Earth and transfer that motion to a craft to which it is rigidly attached. The corresponding motion of the craft in the vertical is defined as along the z-axis. It is also important to devise a means to cause translation in the direction transverse to the radial direction of gravity. The direction tangential to the gravitating body's surface and perpendicular to the axis of gravity is defined as the xy-plane. Consider the case that craft may be caused to spin, and the resulting spin may be used to translate the craft in a direction tangential to the gravitating body's surface. The rotational kinetic energy can be converted to translational energy as shown in detail infra.

Specifically, the craft may comprise a plurality of fifth force units each comprising a source of pseudoelectrons and a converter such as a set of charged capacitor plates to convert the lift on the pseudoelectrons. The units may be spatial distributed and capable of being individually controlled in time. The units may be synchronously activated and deactivated in phase units to cause a wave of upward lift and downward falling motion that travels along the perimeter of the craft to cause the craft to wobble about its center of mass, rotating about the craft's center of mass. The circumferential spatially traveling wobble cause the craft to spin about its center of mass and acquire angular momentum along the vertical axis at this point.

Using the plurality of units of controllable vertical lift, the fifth force can be made variable in any direction in the xy-plane of an aerospace vehicle to be tangentially accelerated such that the spinning vehicle can be made to tilt to change the direction of its spin angular momentum vector. Conservation of angular momentum stored in the craft along the z-axis results in horizontal acceleration. Thus, the vehicle to be tangentially accelerated possesses a cylindrically or spherically symmetrically rotatable mass having a moment of inertia that serves as a flywheel. By controlling the plurality of fifth-force devices located around the perimeter of the craft to control the vertical forces in the xy-plane an imbalance in the wobble can be controllably created to tilt the craft and cause a precession resulting in horizontal translation of the craft.

A disc that resembles a flywheel is ideal craft geometry with the fifth force units about the perimeter wherein the wobble motion wave travels along its perimeter. Then, the rotating craft can be caused to translate in the transverse direction to the gravitational axis by tilting the angular momentum vector of the craft in a controlled manner to cause a precession force perpendicular to the angular momentum vector and the resultant vector of the gravitational and fifth forces. The transverse precession may be controlled to cause a transverse transport of the vehicle.

Specifically, as the angular momentum vector is reoriented from parallel with respect to the radial vector to tilted, a torque is produced on the flywheel due to the force balance of the central force of gravity on the gravitating body, the resultant fifth force of the plurality of units, and the angular momentum of the flywheel device. The resulting acceleration, which conserves angular momentum, is perpendicular to the plane formed by the gravitating body's radial vector and the angular momentum vector. Thus, the resulting acceleration is tangential to the surface of the gravitating body. Large translational velocities are achievable by executing a trajectory that is vertical followed by a transverse precessional translation with a large radius while the craft also undergoes a controlled fall or wobble which increases the precessional radius.

### Mechanics

The body to be levitated may acquire spin by causing it to wobble. The body to be levitated may comprise a plurality of lifting devices around the perimeter. The plurality of devices could increase and decrease their lift force as a harmonic wave around the perimeter such that the traveling torque in the plane of the body such as that of a vehicle such as a planar or disc-shaped one rotates around an axis perpendicular to the plane. In an embodiment, the vertical symmetry axis is tilted relative to the vertical z-axis of the Earth as a reference frame to become the z′-axis, and the z′-axis is caused to precess about the z-axis to impart angular momentum along the z-axis. In an embodiment, the motion of causing the z′-axis to precess about the z-axis comprises a wobble. This plane can be titled by the devices such that a transverse precession gives rise to transverse transport of the vehicle. Specifically, the z-axis may be tilted to cause the vehicle to precess to give rise to transverse translation.

### Analytical Mechanical Analysis of the Fifth Force Craft Wobble Motion

Euler's equations for free rotation of a rigid body are given by [39]

I₁\dot{ω}₁=(I₂−I₃)ω₂ω₃ (35.117)

I₂\dot{ω}₂=(I₃−I₁)ω₃ω₁ (35.118)

I₃\dot{ω}₃=(I₁−I₂)ω₁ω₂ (35.119)

For a circular disk craft of radius R mass M and relative negligible thickness, the principal moments of inertia are

I₁=I₂=1/4MR² (35.120)

I₃=1/2MR²=2I₁ (35.121)

The third Euler equation reduces to

ω₃=0 (35.122)

### Thus,

ω₃=const (35.123)

This is the angular velocity of the disc craft about its axis of symmetry, and is taken as one of the initial conditions. The first two Euler equations are then satisfied by

$$\begin{matrix}{ω}_{1} ( t ) = \sqrt{{ω}^{2} - ω \frac{2}{3}} sin Ω t & ( 35.124 ) \\ {ω}_{2} ( t ) = \sqrt{{ω}^{2} - ω \frac{2}{3}} cos Ω t \\ where & ( 35.125 ) \\ Ω = \frac{{I}_{1} - {I}_{3}}{{I}_{1}} {ω}_{3} = - {ω}_{3} & ( 35.126 )\end{matrix}$$

The motion of the rigid body in the space-fixed frame can be expressed in terms of the Euler angles θ,φ,ψ, using the relations

ω₁=\dot{θ} cos ψ+\dot{φ} sin θ sin ψ (35.127)

ω₂=−\dot{θ} sin ψ+φ sin θ cos ψ (35.128)

ω₃=\dot{ψ}+\dot{φ} cos θ (35.129)

If the axis of the disc is initially inclined by an angle θ from the vertical, with an angular velocity ω₃, then the motion of the disc is given by

$$\begin{matrix}φ ( t ) = \frac{{I}_{3} {ω}_{3}}{{I}_{1} cos θ} t = \frac{2 {ω}_{3}}{cos θ} t & ( 35.130 ) \\ ψ ( t ) = Ω t = - {ω}_{3} t & ( 35.131 ) \\ θ ( t ) = θ = const & ( 35.132 )\end{matrix}$$

The rotation of the disc is represented by ψ(t), while its precession or “wobbling” is given by φ(t). As θ approaches 0, the wobbling frequency approaches twice the rotation frequency, but the wobbling amplitude also decreases.

### Analytical Mechanical Analysis of the Fifth Force Craft Precessional Transverse Translational Motion

During the translational acceleration in the xy-plane, energy stored in the flywheel is converted to kinetic energy of the vehicle. As the radius of the precession goes to infinity the rotational energy is entirely converted into transitional kinetic energy. The equation for rotational kinetic energy, E_{R}, and translational kinetic energy, E_{T}, are given as follows:

E_{R}=1/2Iω² (35.133)

where I is the moment of inertia and ω is the angular rotational frequency:

E_{T}=1/2mv² (35.134)

where m is the total mass and v is the translational velocity of the craft. The equation for the moment of inertia, I, of the flywheel is given as:

I=ρmᵢr² (35.135)

where mᵢ is the infinitesimal mass at a distance r from the center of mass. Eqs. (35.133) and (35.135) demonstrate that the rotational kinetic energy stored for a given mass is maximized by maximizing the distance of the mass from the center of mass. Thus, ideal design parameters are cylindrical symmetry with the rotating mass, flywheel, at the perimeter of the vehicle.

The equation that describes the motion of the vehicle with a moment of inertia, I , a spin moment of inertial, Iₛ, a total mass, m, and a spin frequency of its flywheel of S is given as follows:

$$\begin{matrix}mg l sin θ = I \ddot{θ} + {I}_{s} S \dot{φ} sin θ - I {\dot{ φ}}^{2} cos θ sin θ & ( 35.136 ) \\ 0 = I \frac{d}{dt} ( \dot{φ} sin θ ) - {I}_{s} S \dot{θ} + I \dot{θ} \dot{φ} cos θ & ( 35.137 ) \\ 0 = {I}_{s} \dot{S} & ( 35.138 )\end{matrix}$$

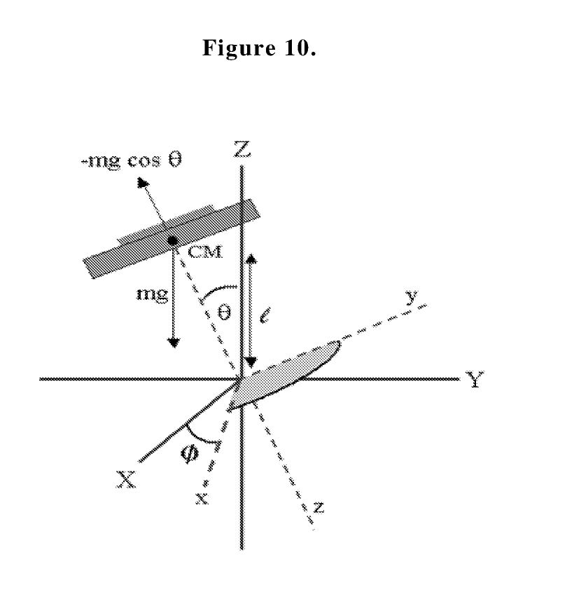

The schematic for the parameters of Eqs. (35.136-35.138) appears in FIG. 10 where θ is the tilt angle between the radial vector and the angular momentum vector, \ddot{θ} is the acceleration of the tilt angle θ, g is the acceleration due to gravity, l is the height to which the vehicle levitates, and \dot{φ} is the angular precession frequency resulting from the torque which is a consequence of tilting the craft. FIG. 10 is a schematic of the forces on a spinning craft that is caused to tilt. Eq. (35.138) shows that S, the spin of the craft about the symmetry axis, remains constant. Also, the component of the angular momentum along that axis is constant.

L_{z}=lₛS=constant (35.139)

Eq. (35.137) is then equivalent to

$$0 = \frac{d}{dt} ( I \dot{φ} {sin}^{2} θ + {I}_{s} S cos θ ) \qquad ( 35.140 )$$

so that

I\dot{φ} sin²θ+IₛS cos θ=B=constant (35.141)

If there is no drag acting on the spinning craft to dissipate its energy, E, then the total energy, E, equal to the kinetic, T, and potential, V, remains constant:

1/2(Iωₓ²+Iω_{y}²+IₛS²)+mgl cos θ=E (35.142)

or equivalently in terms of Eulerian angles,

1/2(I\dot{θ}²+I\dot{φ}² sin²θ+IₛS²)+mgl cos θ=E (35.143)

From Eq. (35.141), \dot{φ} may be solved and substituted into Eq. (35.143). The result is

$$\frac{1}{2} I {\dot{ θ}}^{2} + \frac{{( B - {I}_{s} S cos θ )}^{2}}{2 I {sin}^{2} θ} + \frac{1}{2} {I}_{s} {S}^{2} + mgl cos θ = E \qquad ( 35.144 )$$

which is entirely in terms of θ. Eq. (35.144) permits θ to be obtained as a function of time t by integration. The following substitution may be made:

u=cos θ (35.145)

### Then

\dot{u}=−(sin θ)\dot{θ}=−(1−u²)^{1/2}\dot{θ} (35.146)

Eq. (35.144) is then

\dot{u}²=(1−u²)(2E−IₛS²−2mglu)I⁻¹−(B−IₛSu)²I⁻² (35.147)

or

\dot{u}²=f(u) (35.148)

from which u (hence θ) may be solved as a function of t by integration:

$$t = \int \frac{d u}{\sqrt{f ( u )}} \qquad ( 35.149 )$$

In Eq. (35.149), f(u) is a cubic polynomial, thus, the integration may be carried out in terms of elliptic functions. Then, the precession velocity, \dot{φ}, may be solved by substitution of θ into Eq. (35.141) wherein the constant B is the initial angular momentum of the craft along the spin axis, IₛS given by Eq. (35.139). The radius of the precession is given by

R=l sin θ (35.150)

And the linear velocity, v, of the precession is given by

v=R\dot{φ} (35.151)

The maximum rotational speed for steel is approximately 1100 m/sec [40]. For a craft with a radius of 10 m , the corresponding angular velocity is

$$\frac{110 cycles}{sec} .$$

In the case that most of the mass of 10⁶ kg was at this radius, the initial rotation energy (Eq. (35.133)) is 2.4×10¹³ J . As the craft tilts and changes altitude (increases or decreases), the vertical force imbalance in the xy-plane pushes the craft away from the axis that is radial with respect to the Earth. For example, as the craft tilts and falls or wobbles, the created imbalance pushes the craft into a trajectory, which is analogous to that of a gyroscope as shown in FIG. 35.10. From FIG. 35.10, the force provided by the fifth force along the tilted z-axis (mg cos θ) may be less than the force to counter that of gravity on the craft. From Eq. (35.141), the rotational energy is transferred from the initial spin to the precession as the angle 0 increases. From Eq. (35.142), the precessional energy may become essentially equal to the initial rotational energy plus the initial gravitational potential energy. Thus, the linear velocity of the craft may reach approximately 6900 m/sec (15,400 mph). During the transfer wherein the mechanics of descending is used, the craft falls approximately one half the distance of the radius of the precession of the center of mass about the Z-axis. Thus, the initial vertical height, l, must be greater.

The fifth-force devices can also be controlled to cause the craft to follow a pseudo-orbit about a gravitating body to achieve a gravity assist to further propel the craft. In the cases of solar system and interstellar travel, unconventional velocities may be obtained by using gravity assists from massive gravitating bodies wherein the fifth-force capability of the craft establishes the desired trajectory to maximize the assist. The energy imparted to the craft is conserved between the craft and the gravitating body wherein the translational energy imparted to the craft causes an increase in the curvature of spacetime of the gravitational body and a decrease in its gravitational potential energy.

### Embodiments of a Propulsion Device

In embodiments, pseudoelectrons are formed from free electrons by at least one of direct absorption of a high-energy photon and by photon absorption comprising field scattering from sources such as at least one of electric, magnetic, and electromagnetic fields. The fields may comprise at least one of nuclear fields, atomic electron fields such as those of inner shell electrons, and external electric, magnetic, and electromagnetic fields. In an embodiment, the electric field may be as high as about the critical field such as

$${E}_{0} = \frac{{m}^{2} {c}^{3}}{e ℏ} = 1.32 \times {10}^{6} V \text{/} cm$$

corresponding to a magnetic field B₀=4.41×10⁹ T. The electric field may in at least one range of about 10³ V/cm to 10¹⁶ V/cm, 10⁵ V/cm to 10¹⁴ V/cm, and 10⁷ V/cm to 10¹² V/cm. The magnetic field may be in at least one range of about 0.1 T to 10¹⁰ T, 1 T to 10⁸ T, and 3 T to 10⁶ T. The scattering may cause high-energy photon emission that is absorbed by the free electron to form a pseudoelectron. The electric field may be that of a charged particle such as a nucleus. The magnetic field may be a multipole field such as a dipole or a quadrupole field.

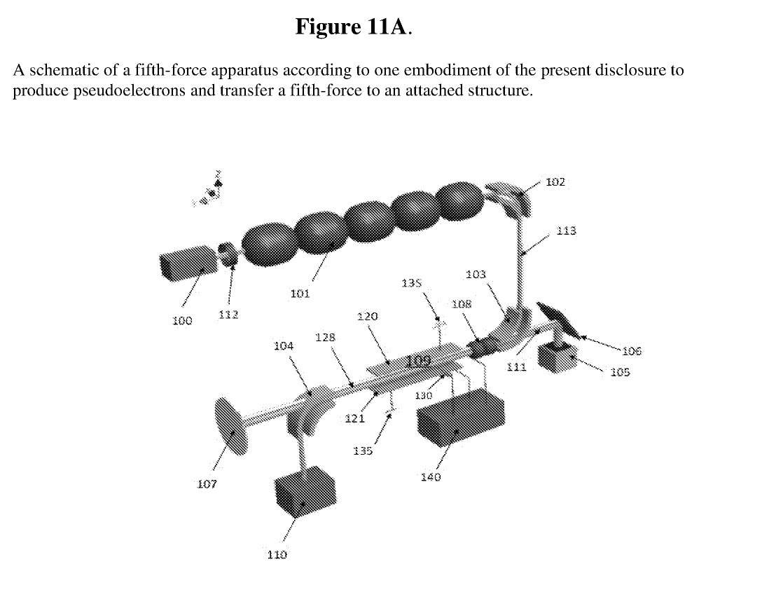

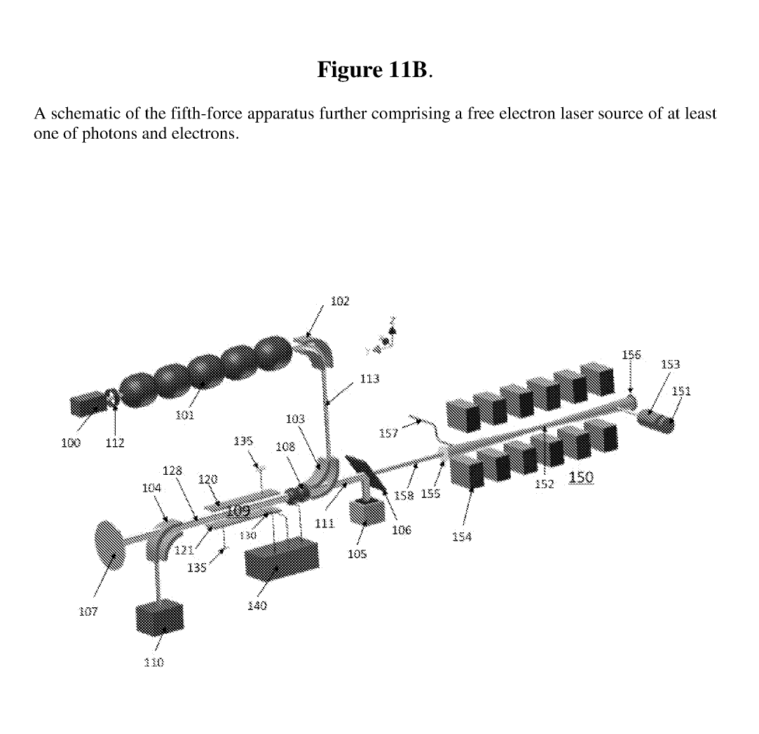

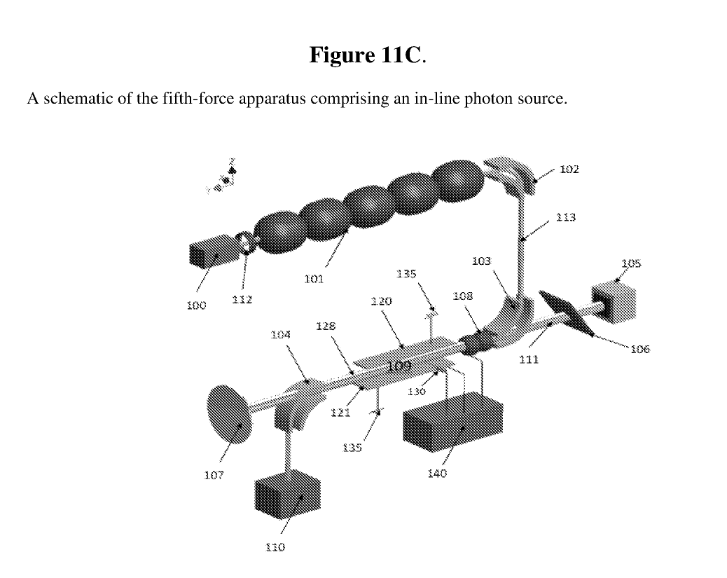

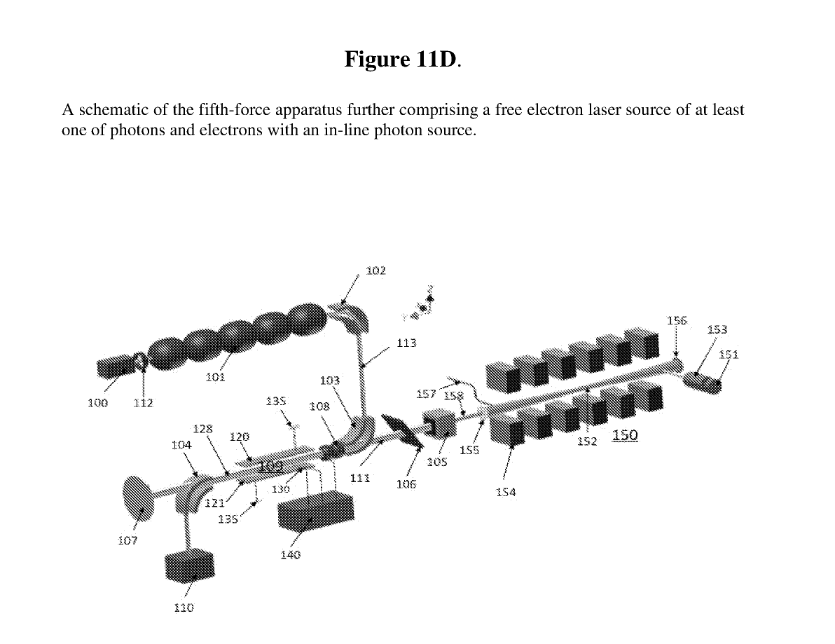

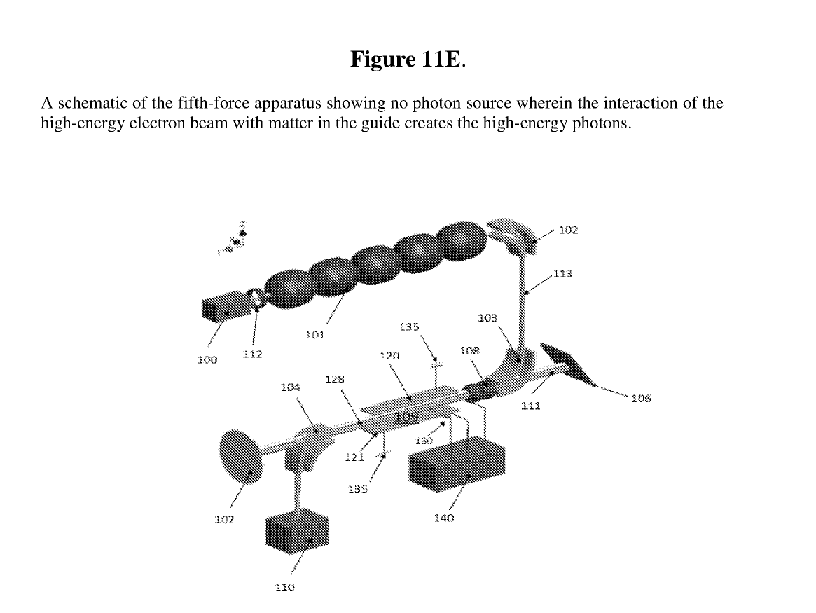

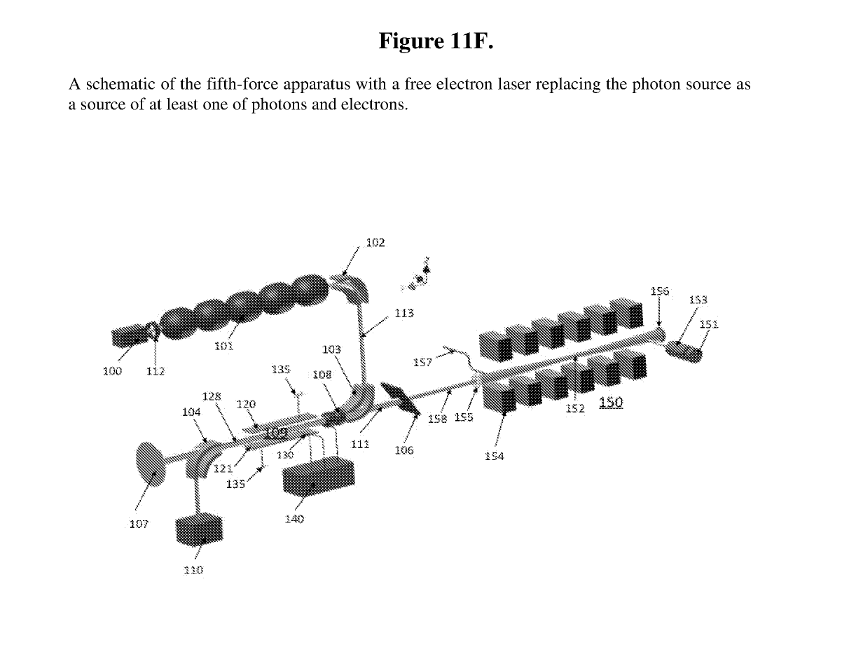

Systems of the following embodiments such as field generators and controllers, power supplies, beam recovery devices and other systems of the disclosure comprise embodiments of the fifth force device shown in FIGS. 9A-9D. Other systems performing the same function known to those skilled in the art may be used in lieu of the systems of the disclosure. As shown in FIGS. 11A-11F, the apparatus for providing the fifth force comprises a means to inject electrons and a guide means to guide the electrons. Pseudoelectrons may be produced from the propagating guided electrons by application of one or more of i.) high-energy photons from a source 105 or generated from intrinsic energy such as kinetic energy, ii.) an electric field, iii.) a magnetic field, and iv.) an electromagnetic field. The fields may be provided by a field source means such as external source 109 or those inherent to matter such as gaseous, liquid, or condensed matter. The propagating pseudoelectrons may be repelled from the gravitational field of a gravitating body due to the fifth force. A field source means 109 may provide an opposite force to the repulsive fifth force on the pseudoelectrons. Thus, the repulsive fifth force may be transferred to the field source and the guide 109, which may further transfer the force to the structure to be at least one of levitated and propelled by structural attachment 135. Once the antigravitational energy has been extracted from the pseudoelectrons, the upward force may be diminished to the level that the electrons may be recovered to maintain electroneutrality of the F² device. A circuit such as a collection electrode 121 or beam dump 110 may recover the spent pseudoelectrons.

In an embodiment, the propulsion means shown schematically in FIG. 11A comprises an electron beam source 100, and an electron accelerator module 101, such as at least one of an electron gun, an electron storage ring, a radiofrequency linac, an introduction linac, an electrostatic accelerator, betatron, synchrotron, a microtron, a high voltage power supply, and a capacitor bank charged to high voltage such as 2000 kV. Focusing means 112, such as a magnetic or electrostatic lens, a solenoid, a quadrupole magnet, or a laser beam may focus the beam 113. The electron beam 113 may be directed into a channel of electron guide 109, by beam directing means 102 and 103, such as dipole magnets. In an embodiment, pseudoelectrons are produced by the interaction of the free electrons and high-energy photons. The photons may comprise a beam 111 from source 105. The photons may reflected from mirror 106 into the channel 109 (FIG. 11A and FIG. 11B), or the photon beam 111 such as one comprising high-energy photons such as at least one of X-ray and gamma ray photons may be aligned on-axis with the channel 109 (FIGS. 11C and FIG. 11D). The aligned gamma beam source 105 may comprise a free electron laser 150, Bremsstrahlung source, inverse Compton scattering source, or radioactive source (FIGS. 11B, 11D, and 11F). In an embodiment, the electron guide channel and field source 109 is powered by a field generating power source 140 to produce an electric or magnetic force in the direction opposite to direction of the antigravitational or fifth force. In an exemplary embodiment wherein the fifth force is z-axis directed as shown in FIGS. 35.11A-F, the field generating power supply, analyzer, and controller 140, powers an electric force in capacitor 109. The electric field of the capacitor 109 along the z-axis opposes the lift on the pseudoelectrons. The electric field opposes the fifth force via a potential provided by grid electrodes 120 and 121 of capacitor 109. The electric field may be constant in time or vary in time. The electric field may be linear with distance between the electrodes 120 and 121, or it may be variable with distance. The electric potential across the electrodes may be constant or varying in time. The electric force opposing the lift on the pseudoelectrons may provide work against the gravitational field of the gravitating body as the pseudoelectron propagates along the channel of the guide means and field producing means 109. The resulting work may be transferred to the means to be propelled via its attachment to field producing means 109 such as structural support 135.

The electric or magnetic force of field producing means 109 may be variable until force balance with the repulsive fifth force may be achieved. In the absence of force balance, the pseudoelectrons may be accelerated, and the emittance of the beam may increase. Also, the accelerated pseudoelectrons may radiate; thus, the drop in emittance and/or the absence of radiation is a signal that force balance is achieved. The emittance and/or radiation may be detected by sensor 130, such as a photomultiplier tube, and the signal may be used in a feedback mode by capacitor 109 power supply, analyzer, and controller 140 which varies the electric or magnetic force by controlling the electric potential or strength of dipole magnets of (field producing) means 109 to control force balance to maximize the lift of the F² device.

In one embodiment, the field source 109 further provides an electric or magnetic field that facilitates production of pseudoelectrons of the electron beam 113. Focusing or guiding at least one of the input electron beam 113 and the formed pseudoelectron beam may facilitate the production of pseudoelectrons. The pseudoelectrons may be produced from the electron beam 113 by the absorption of photons from photon beam 111 provided by a photon source 105, such as a high intensity photon source, such as a laser such as an inverse Compton scattering device or a free electron laser (FEL) 150 (FIGS. 11B, 11D, and 11F). In an embodiment, the light source 105 comprises a tunable gamma-ray light source based on Compton scattering between a high-brightness, relativistic electron beam 152 and a high intensity laser pulse produced via chirped-pulse amplification (CPA). In an embodiment, a precision, the tunable mono-energetic gamma ray source may be driven by a compact, high-gradient X-band linac, a betatron, or a synchrotron. High brightness, relativistic electron bunches may be produced by an X-band linac that interact with a Joule-class, 10 ps, diode-pumped CPA laser pulse to generate tunable rays such as in the 40 MeV to 100 MeV photon energy range via Compton scattering. The light may comprise high-energy light such as X-rays or gamma rays. In an embodiment, electron-irradiating photons having energy below the threshold for forming a pseudoelectron may be boosted in energy to the threshold energy for pseudoelectron production by the inverse Compton effect wherein the initial kinetic energy of the electron may provide the additional photon energy and the remaining kinetic energy required for the formation of the pseudoelectron. The photons that are boosted in energy by the inverse Compton effect may be in the visible or ultraviolet wavelength range. In that case, the photon source 105 may comprise a corresponding laser. The laser radiation 111 can be confined to a resonator cavity by mirrors 106 and 107.

In a further embodiment, pseudoelectrons are produced from the electron beam 113 by photons from the photon source 105 that may also be collinear with the guide 109 (FIGS. 11C and 11D). The orientation of the laser radiation or the resonator cavity relative to the propagation direction of the electrons may be such that the cross section for pseudoelectron production is maximized.

Following the propagation through the field generating means 109 in which propulsion work is extracted from the beam 113, the output beam 128, may be directed into electron-beam dump 110 by beam directing apparatus 104, such as a dipole magnet. In a further embodiment, the beam dump 110 may be replaced by a means to recover the remaining energy of the output beam 128 such as a means to recirculate the beam or recover its energy by electrostatic deceleration or deceleration in a radio frequency-excited linear accelerator structure 110. Feldman [41] describes these means that and is incorporated herein by reference in its entirety.

The present F² device comprises high current and high-energy beams and related systems of free electron lasers. Such systems are described in Nuclear Instruments and Methods in Physics Research [42,43] that are incorporated herein by reference in their entirety. In an embodiment, the free electron laser 150 of FIGS. 11B, 11D, and 11F comprises a FEL electron gun 151 that supplies electrons to a FEL electron beam 152. The beam 152 is output from the FEL electron accelerator 153 that increases the electron velocity such as up to relativistic velocities. The high-energy electron beam 152 travels through the FEL undulator magnets 154 and produces an output photon beam 158. In the case that the FEL outputs laser light 158 that is capable of being reflected, the FEL further comprises FEL mirrors 155 and 156. In the case of very high-energy light such as the desired X-ray and gamma ray photons, the light beam 111 may be directly input to the electron guide and capacitor 109 wherein the photon beam 111 may be axially aligned with the guide channel 109 and the electron beam 113 there within. Following emission in the FEL undulator 154, the FEL electron beam may output to the electron beam output to energy recovery and recirculation systems 157. In another embodiment, the FEL light beam 158 comprises the y-axis-directed light beam 111, and the FEL undulated electron beam outputs to comprise y-axis-directed electron beam 113.

In another embodiment shown in FIGS. 11A-F, at least one of the electrons that form pseudoelectrons and pseudoelectrons are accelerated to relativistic energies by an acceleration means such as bean channel accelerator 108 before entering or within the capacitor means 109 to provide relativistic pseudoelectrons with increased negative gravitational energy to be converted to lift energy as the F² device produces lift. The effect of increasing the relativistic pseudoelectron mass may be according to the relativistic mass portion of Eq. (35.106).

In an embodiment, high-energy light such as at least one of X-rays and gamma rays such as beam 111 is incident matter such as at least one of gaseous, liquid, and solid matter that is a source of electrons. In an embodiment, the matter comprises at least one of a metal and a superconductor having extended electron planes that may have a larger cross section for interaction with the high-energy photons to form pseudoelectrons. Exemplary superconducting materials are niobium-titanium that can support 15 T and Nb₃Sn that can support fields up to 30 T. Additional exemplary materials are high-temperature superconductors such as bismuth strontium calcium copper oxide (BSCCO) that can support 5×10⁵ A/cm², yttrium barium copper oxide (YBCO) that can support 120 T parallel and 250 T perpendicular to the copper oxide planes, and magnesium diboride. The matter may be cryo-cooled by at least one of a cyropump and a cryogen wherein the matter may be maintained in or in contact with a dewar. The matter may comprise nuclei with a high nuclear charge (high Z) having tightly bound electrons with relativistic velocities that may have a higher cross section for interacting with the high-energy photons and forming pseudoelectrons. Suitable bound electrons of the material may provide the electron velocity and kinetic energy required to form a pseudoelectron wherein any kinetic energy deficit may be provided by the compensatory energy of the incident X-rays or gamma rays. The sum of the kinetic energy of the initially bound electron and any compensatory energy may be about or greater than that of Eq. (35.98). The targets may comprise ionic or metallic crystals wherein the beam may be oriented in a direction relative to a desired crystallographic axis to get coherent or enhanced desired effects of at least one of radiation such as inverse Compton effect radiation and pseudoelectron production. The photons may interact with the electrons to form pseudoelectrons. Rather than dissipation by collision and thermalization in the matter, the negative gravitational potential energy and upward force on the pseudoelectrons may be transduced to a force on the matter. The transduction may be achieved by applying a field to the pseudoelectrons in the matter. The field may be at least one of an electric or magnetic field. The F² device may comprise two parallel plates that comprise a capacitor 109 that contain the irradiated matter. The upward antigravitational force on the negatively charged pseudoelectrons may be transferred to the capacitor 109 by charging the plates to repel the electrons in the opposite direction of the antigravitational force.

To create lift, pseudoelectrons may be formed in the matter or outside of the matter from high-energy electrons incident the matter. The incident high-energy electrons may produce the high-energy photons as well as the kinetic energy (Eq. (35.91)) to satisfy the condition to form pseudoelectrons such as according to Eq. (35.98). An exemplary embodiment is shown in FIG. 11E. In another embodiment, the matter may comprise at least one target of incident high-energy electrons such as from beam 113. The interaction of the electrons with the matter of the target causes Bremsstrahlung radiation to be produced by a portion of the incident electrons. The radiation may be at least one of X-ray and gamma ray photons. The material may have a high nuclear charge Z to favor both Bremsstrahlung radiation and pseudoelectron formation. The targets may comprise ionic or metallic crystals wherein the beam may be oriented in a direction relative to a desired crystallographic axis to get coherent or enhanced desired effects of at least one of radiation and pseudoelectron production. In another embodiment, the high-energy radiation may be created by collisions of high energy particles such as protons or ions with the target to produce radiation by collisional ionization of an inner shell electron of the atoms of the matter of the target and by other mechanisms known in the art such Auger cascade and Bremsstrahlung. The targets such as a plurality of metal films such as X-ray or gamma ray anodes may permit passage of a portion of the incident electrons from beam 113 with sufficient energy for pseudoelectron production when incident the Bremsstrahlung radiation. The targets such as anodes may be cooled. The Bremsstrahlung radiation may exist in the target and may propagate outside of the target. The targets may comprise at least one window to facilitate the passage of the portion of the incident electrons. The electrons may be focused by a focus means such as means 109 to cause interaction with the Bremsstrahlung radiation. The means to focus the electrons may comprise at least one of a source of external and internal electric, magnetic, and electromagnetic fields. At least a portion of the incident high-energy electrons may interact with the high-energy photons to form pseudoelectrons. The pseudoelectrons may form inside or outside of the matter from the interaction of the high-energy photons and electrons inside or outside of the matter. In the case that pseudoelectrons form or exist in the matter, the matter may be sufficiently thin such that the pseudoelectrons may propagate out of the matter to form free pseudoelectrons. Alternatively, the pseudoelectrons may remain trapped in the matter. The pseudoelectrons may be created in between the parallel plates of the capacitor 109 that transduces the upward force on the pseudoelectrons into lift on the capacitor and any structure rigidly attached by structural support 135.

In an embodiment, high-energy photons and electrons may be formed by the Mossbauer effect wherein resonant nuclear absorption of X-rays or gamma rays from a source such as 105 of FIG. 11C de-excites by emission of a high-energy photon that ionizes an inner shell electron to cause a cascade of electrons and photons to be released. The cascade may comprise an Auger cascade. The emitted electrons such as high-energy electrons and at least one of the high-energy emitted and incident photons may interact to form pseudoelectrons. The Mossbauer absorber may be positioned in between the plates of the capacitor 109. The Mossbauer source may comprise photon source 105 that may be co-axial with guide 109 (FIG. 11C).

The capacitor may be charged with a high-voltage supply 140 to create the electric field. The direction of the electric force on the pseudoelectrons may be antiparallel to the antigravitational force such that the plates experience lift. An object to be lifted may be rigidly fastened to the capacitor plates by structural attachments 135. The irradiation intensity, and consequently the yield of pseudoelectrons may be sufficient to cause net lift over the gravitational force on the matter. The matter may be selected to provide maximum lift per photon irradiation applied. The selection may be based on pseudoelectron formation cross section that may depend on nuclear charge Z, the electron density, and bound electron energies. The selection may also be based on pseudoelectron scattering and decay mechanisms and cross sections.

In an embodiment, the F² device comprises a source of free electrons having kinetic energy sufficient to form a pseudoelectron. The source may comprise a cathode such as a photocathode or thermionic cathode 100. The electrons may be emitted and maintained in a low-pressure vessel such as a vacuum vessel. The electrons may be confined by at least one of electric and magnetic fields. The device may comprise at least one of a magnetic and electrostatic bottle to provide free electron confinement. Other means are toroidal or selenoidal magnetic field sources and Penning traps. The vessel may enclose capacitor 109 wherein plate 120 and 121 may comprise at least a portion of the top and bottom walls, respectively. In an embodiment, the F² device further comprises a source of high-energy photons 105 and 150 to be absorbed by the free electrons to form pseudoelectrons. The source of high-energy photons may be in the wavelength region of X-rays to gamma rays. The source of high-energy photons may be in the energy region of 0.5 MeV to 500 MeV. The source of photons may be a radioactive source, a free electron laser, an undulator, a Bremsstrahlung device, and a synchrotron. The photons may be supplied through a window such as an X-ray or gamma ray transparent window such as a beryllium window. In the case that the inverse Compton effect increases the photon energy, the photons may be supplied through a transparent optical window such as a UV transparent window such as a MgF₂ or sapphire window.

In an embodiment, at least one of high-energy electrons and high-energy photons are emitted from a plurality of electrodes such as at least one of set of electrodes comprising a cathode and an anode. The F² device may further comprise a vacuum chamber that may serve as a vessel, a gas supply, a pump such as at least one of a mechanical pump such as a Scroll, diagram, turbo, and a rotary pump and a cyropump, and pressure gauge and controller. The chamber may be shield with a Faraday cage. The vessel and any leads into the cell may be electrically insulated to avoid shorting. The electrode vessel penetrations may comprise high-voltage feed throughs. The electrodes may be housed in the vessel capable of a vacuum wherein the pressure of an added gas such as hydrogen, nitrogen, or an inert gas such as helium may be maintained in the range of 1 uTorr to 10 Torr. The electrodes may comprise the electrodes 120 and 121 of the capacitor 109. The cathode may comprise the upper electrode 120. Alternatively, the electrodes may be oriented perpendicularly to the electrodes 120 and 121 and positioned to cause at least one of the high-energy electrons and high-energy photons to be emitted into the channel 109. The photons may comprise at least one of X-rays and gamma rays. The photons may comprise Bremsstrahlung radiation. The accelerated high-energy electrons may emit Bremsstrahlung radiation. At least one electrode may be at least partially transparent to at least one of high-energy electrons and high-energy photons. At least one electrode may comprise a grid electrode. The electrodes may be charged to high voltage by a high voltage power supply such as 140. The electrode voltage may in at least one range of about 500 kV to 500 MV, 1 MV to 200 MV, and 2 MV to 100 MV. The voltage may be sufficient such that the kinetic energy of the emitted electrons and the energy of the emitted photons are sufficient to form pseudoelectrons. In an embodiment, pseudoelectron production has the minimum energy gamma photon energy requirements for production of 46.8×10⁶ eV (Eq. (35.98)). In an embodiment, the kinetic energy of the electron may provide at least some of the production energy. The sum of the photon energy and the electron kinetic energy may be above the minimum for pseudoelectron production wherein one may compensate for a deficit in the other. A majority of the voltage of the discharge between the set of electrodes may occur in the cathode fall region. The cathode may comprise an emitter of at least one of the high-energy electrons and the high-energy photons. The electrodes may have any desired shape that enhances the yield of pseudoelectron production such as planar, spherical, hemispherical, concave, and convex.

The electrodes may be pulse discharged. The pulse discharge may be provided by the power supply 140 that may comprise a pulsed power supply. The power supply 140 may comprise high-voltage capacitors that are charged and pulsed discharged. The pulse discharge of the electrodes may give rise to a high voltage spike due to the circuit reactance. The high-voltage spike may also boost the energy of at least one of the high-energy electrons and the high-energy photons. The high-energy photons may comprise Bremsstrahlung radiation. The discharge circuit may comprise a switch that may discharge the electrodes at high frequency such as at least within one range of about 10 Hz to 1 THz, 100 Hz to 10 GHz, 1 kHz to 100 MHz, and 1 kHz to 10 MHz. The discharge duration may be in at least one range of 100 ns to 100 ms, 10 ns to 1 ms, and 0.1 us to 10 us. The switching may be performed electronically by means such as at least one of an insulated gate bipolar transistor (IGBT), thyristor, a silicon controlled rectifier (SCR), and at least one metal oxide semiconductor field effect transistor (MOSFET). Alternatively, ignition may be switched mechanically. The vacuum vessel such as the one about the capacitor 109 may further comprise further a selenoidal magnetic field that may be supplied with pulsed power from a pulse power supply such as 140. The magnetic power may be coincident with the electrode power to produce a magnetic field to focus the electrons emitted from the cathode onto the anode.

The discharge voltage may be charged by at least one of a Van de Graaf generator and a high voltage pulse generator. Alternatively, the pulse generator may comprise a Marx type or Arkadjev-Marx type comprising a plurality of capacitors connected in parallel and charged to a lower voltage than that of the pulse such as to 50 to 100 kV each using a high voltage charger such as a high voltage transformer and a diode bridge. The capacitors may be separate by resistors such as ones having a resistance in the range of about 10 kohm to 1000 kohm. The capacitors may be charged to the parallel voltage that will give the desired output voltage when the capacitors are switched from parallel to series connections. The discharge such as a 10 MV pulsed discharge may be triggered by sending a synchronized pulse to the electrode contacts. Increasing the electrode separation and lowering the pressure in the vessel may increase the maximum output voltage. The voltage may be measured with a high voltage probe, and the current may be measured with a Rogowski coil.

In an embodiment, the higher energy electrons and photons are produced in a pulsed discharge such as a pinch discharge. The pinch discharge may comprise the consumption of a solid material such as a wire. The discharge system may comprise a Z pinch machine. An initially high voltage may form plasma of the solid material wherein the plasma transitions into a high current discharge such as an arc discharge. The voltage and current may be provided by discharge of high voltage capacitors. At least one of the gamma rays and high-energy electrons may be formed in the discharge that subsequently interacts to form pseudoelectrons.

Furthermore, as in the case of free electrons in superfluid helium, in an embodiment, pseudoelectrons may be capable of absorbing specific frequencies of high-energy light to transition to at least one of a pseudoelectron state and higher energy pseudoelectron states corresponding to reduced radii. By this means, the fifth force may be increased. The F² device of the present disclosure further comprises a photon source such as a short wavelength light source such as a laser such as a free electron laser (FEL) to cause transitions of pseudoelectron to the reduce-radii states. The position of the photon source 105 or 150 is shown in FIGS. 11A, 11B, 1C, 11D, and 11F.

In an embodiment, the charge separation created by the pseudoelectrons such as the separation at vertically separated electrodes such as 120 and 121 may be harnessed as electrical power. Thus, the means to collect pseudoelectrons such as electrodes 120 and 121 of field generating means 109 (FIGS. 35.11A-F) and may comprise a direct electrical power converter of the power released by means such as a source of at least one of X-rays and gamma rays such as a nuclear power source such as one comprising radioactive decay, fission, or fusion power.

In an embodiment, an object may be charged with pseudoelectrons by directing a flow or beam onto the object to cause it to lift.

In an embodiment, pseudoelectrons are formed from the supercurrent current by a high electric field. The electric field may be created in the superconductor. One means is by distortion of the lattice. The superconductor may comprise a superconducting element of a circuit otherwise comprising normal conducting circuit elements. An exemplary superconductor element comprises a disc with end caps that serve as circuit connections. The lattice of the superconductor may be distorted by pressure applied by means known in the art such as mechanically or magnetically. The rise time of the application of the pressure may be very fast such as in at least one range of about 0.1 ns to 1 s, 1 ns to 100 ms, and 10 ns to 10 ms. The mechanical pressure may be generated by at least one of a mechanical device such as a cam, an electromagnetic device such as a solenoid or speaker-like device, a pneumatic device, a hydraulic device, and a piezoelectric device. In an embodiment, the mechanical pressure may be applied by a thermally expansive element in the superconducting circuit that is rigidly connected to the superconductor element such that it applies mechanical pressure to the superconductor element when heated. The device that applies the pressure may be circumferential to the superconducting element such that the current may flow through the non-circumferential portion of the element. In an exemplary embodiment, a piezoelectric device creates pressure circumferentially to the element as the current flows through the non-circumferential portion of the element. A mechanical device such as a piston driven by an explosive may apply the pressure. The explosive may comprise hydrino reactants. The pressure may be applied intermittently or constantly. A mechanical press may apply the constant pressure across the superconducting element. The press may comprise two superconductor-element end plates, each having an electrical feed through wherein at least one fastener such as bolts or screws connects the plates wherein tightening the fasteners applies mechanical pressure to the superconducting element that is electrically connected in a current carrying circuit to a source of current.

The pressure may be applied by a magnetic field. The magnetic field may be provided by at least one of a permanent magnet and an electromagnet. The magnetic field may be less than the critical magnetic field. The electromagnet may comprise the superconductor. The supercurrent may generate the magnetic field. The magnetic field from the supercurrent may comprise a magnetic pinch. The supercurrent may be pulsed to generate the magnetic pinch. The supercurrent density may be high to create the pinch. The current density may generate the maximum magnetic field less than the critical magnetic field. The critical magnetic field may be in at least one range of about 0.01 T to 500 T, 0.1 T to 400 T, and 0.1 T to 300 T. Exemplary superconducting materials are niobium-titanium that can support 15 T and Nb₃Sn that can support fields up to 30 T. Additional exemplary materials are high-temperature superconductors such as bismuth strontium calcium copper oxide (BSCCO) that can support 5×10⁵ A/cm², yttrium barium copper oxide (YBCO) that can support 120 T parallel and 250 T perpendicular to the copper oxide planes, and magnesium diboride. The electromagnet may comprise another superconductor. The levitation device may comprise a plurality of superconductors elements electrically connected in at least one of parallel and series. At least one element may serve as an electromagnet for at least another of the plurality of superconductor elements. The magnetic field may be greater that the critical current. The critical current may cause the current to quench. The quenching may cause the creation of pressure in the lattice. The lattice may distort due to the pressure to give rise to a high internal electric field that may give rise to pseudoelectrons. The supercurrent density may be in at least one range of about 1×10¹ A/cm² to 1×10⁷ A/cm², 1×10² A/cm² to 1×10⁶ A/cm², and 1×10³ A/cm² to 5×10⁵ A/cm². The voltage may be high or low. The voltage may be in at least one range of 1 microvolt to 100 MV, 1 mV to 10 MV, 1 V to 1 MV, and 1 V to 500 kV. The high current may be supplied by at least one of a capacitor bank and a transformer. The current may be pulsed. The pulsing may cause the pressure that gives rise to lattice distortion and electric field generation. The pulsing may decrease the current skin depth to increase the current density. The increased current density may exceed the critical current. At least one of the current density gradient and the surpassed critical current may result in the pressure and lattice distortion.

In an embodiment, a super current in a large superconductive inductor circuit is quenched. The superconductive current may be quenched by at least one quenching means such as one comprising causing a very fast open circuit, applying a magnetic field that causes the conductivity to go normal, and applying heat that rapidly raises the temperature to causes the conductivity to go normal. The rapid change in flux and high inductance gives rise to a high voltage of the superconducting electron flow. The voltage V may be given by

$$V = L \frac{di}{dt} \qquad ( 35.152 )$$

wherein L is the inductance and i is the current. The circuit is designed such that the high voltage corresponds to a high energy of about 50 MeV that gives rise to pseudoelectrons.

In an embodiment, a high voltage, high current pulse is flowed through a superconductor connected in series to a circuit comprising a normal conductor. The normal conductor may have high conductivity such as copper, aluminum, or silver. The circuit may comprise a high power source such as a bank of high voltage capacitors such as one of about 40 MV or higher. The circuit may be capable of producing high current such as 100 A to 100,000 A. The switch to cause the electrical current pulse through the superconductor may comprise a mechanical switch, a gas gap switch, a thyristor, and others known in the art. The circuit may be pulsed over time to cause a superposition of antigravitational force. In an embodiment, the repetition frequency may about the lifetime of the pseudoelectrons such that the resulting fifth force is about continuous. In another embodiment, the circuit may be powered by a low voltage, high current source such as that provided by a low voltage capacitor bank having capacitors with high capacitance such as Maxell 3400 F capacitors. The circuit may capable of a providing a DC pulse that may be switched on and off repetitively. The switching may be performed electronically by means such as at least one of an insulated gate bipolar transistor (IGBT), a silicon controlled rectifier (SCR), and at least one metal oxide semiconductor field effect transistor (MOSFET). Alternatively, the pulse may be switched mechanically. In an embodiment, the low voltage, high current may comprise alternating current. A transformer circuit such as one of a spot welder may supply the alternating current. The formation of pseudoelectrons may be achieved with a low voltage, high current wherein an exemplary power source comprises a Taylor-Winfield model ND-24-75 spot welder. The circuit may comprise a high inductance. The current may exceed the superconductor quenching current such that a voltage spike occurs to provide high energy to form pseudoelectrons. In another embodiment, the circuit may be switched open while carrying high current. The rapid change in current may cause a voltage spike to provide sufficient energy for the formation of pseudoelectrons. In an embodiment, the low-voltage high current may be quenched at the superconductor by application of a high magnetic field suitable to quench the supercurrent. In an embodiment, the quenched current may give rise to a voltage spike to cause the formation of pseudoelectrons.

In an embodiment, the applied power source comprises high voltage AC or high voltage DC with optional pulsing. The time dependent AC voltage and corresponding varying current may cause quenching of the superconductivity. The voltage pulsing may cause quenching. An intermittent magnetic field may cause quenching of the high voltage DC. In an embodiment, the voltage and current are applied as short pulse widths that may be controlled by closing and opening the voltage-current switch. The duration of the pulse may be controlled by adjusting the gap distance of a spark gap switch. At least one of the resistance, inductance, and capacitance of the circuit of the superconductor element may be changed to change the time constant of the pulse to one desired. The pulse duration may be in at least one range of about 0.001 ns to 10 s, 0.1 ns to ls, 1 ns to 100 ms, 10 ns to 10 ms, 100 ns to 10 ms, 1 us to 10 ms, and 10 ns to 1 ms.

In an embodiment, pseudoelectrons form extended electrons that are accelerated to a kinetic energy above the threshold energy of pseudoelectron production. The threshold energy for pseudoelectron production may be about 45 to 60 MeV. A conductor such as at least one of a metal and a superconductor may comprise extended electrons to serve as a source of pseudoelectrons. The metal may comprise one with a high conductivity such as copper or silver. The conductor may be in various shapes such as a wire, sheet, cylinder, and cavity. The cavity may be cooled to decrease collisions that interfere with pseudoelectron production. The acceleration may produce current that comprises current frequencies. The Fourier transform of the current with time may comprise nonzero frequencies. The circuit for current flow may comprise a circuit with inductance L and capacitance C. The impedance may go to infinity at the resonance frequency a of the LC circuit. The resonance frequency may be given by

$$ω = \frac{1}{\sqrt{LC}} \qquad ( 35.153 )$$

A least one current frequency may be at the resonance frequency. The resonance frequency may be that which causes the impedance to become elevated. The current frequency may cause the impedance to approach infinity. The current may be forced to have the resonance frequency by driving at least one of an external voltage and current at the resonance frequency. In an embodiment, the cavity may be tapered differently in different locations such that the upward projection of the antigravitational force due to the pseudoelectrons has an unbalanced net transverse force component.

In an embodiment, the F² device may comprise a cavity such as a closed cavity that is excited with radiation such as RF radiation. The electrons in by cavity metal may be excited with the RF-excitation to cause currents that may form pseudoelectrons that may form at the resonance frequency. The RF-excitation of current may occur in the cavity. In order to conserve the initial momentum of the flowing electrons of the current, the formation of pseudoelectrons may cause a transverse component of force on the cavity in addition to a vertical force. The cavity may be asymmetrical. The transverse components due to pseudoelectrons formed in differ locations from currents moving in opposing directions may not be balanced such that a net transverse force is generated on the cavity.

The cavity may have at least one of a very high amplitude and Q to boost the energy of the electrons such as conduction electrons to an energy that gives rise to pseudoelectron production. The voltage of the electric field in the cavity such as that of a standing electric field wave may be sufficient to give rise to pseudoelectron production.

In an embodiment, pseudoelectrons flow from the surface of the superconducting element. Increasing the superconducting surface area may increase the number of pseudoelectrons formed. Using superconducting elements of larger area and increasing the number of elements in the circuit may increase the area. The superconductor element may

WO 2017/062488 PCT/US2016/055545 comprise surfaces are not smooth such as textured or roughened surfaces to increase the surface area. In an embodiment, the superconductor element is mounted with capacitor plates that are wide compared to the superconductor element to prevent pseudoelectrons ejected from the superconductor from escaping. In an embodiment, the superconductor element is confined or sealed in a non-conducting cavity that can absorb the pseudoelectrons. The fifth force of the pseudoelectrons is transferred to the cavity and the any attachment. A circuit may comprise a normal resistance shunt to the superconductor such that the current is shunted when the superconductor becomes normal conducting due to a high current pulse. In an embodiment, the device may comprise at least one magnet that may be applied in different orientations to trap the pseudoelectrons and increase their lifetime to increase the duration of the antigravitational force. The magnetic field may be in at least one range of about 0.01 T to 1000 T, 0.1 T to 500 T, 0.1 T to 100 T, and 0.1 T to 10 T.

### Implicit Ranges

It is to be understood by one skilled in the Art that when a specific energy is given certain ranges are tolerable. In one embodiment, the energy is the specified energy within at least one range of a factor of about 0.1 to 1000%, 1 to 500%, 1 to 100%, and 1 to 50%. For example, the magnitude of the negative gravitational energy to form a pseudoelectron may be within at least one range of about 1 keV to 1 TeV, 10 keV to 100 GeV, 100 keV to 10 GeV, 100 keV to 1 GeV, 100 keV to 200 MeV, 100 keV to 100 MeV, and 100 keV to 50 MeV. The energy of the photon to form a pseudoelectron may be in at least one range of about 1 keV to 1 TeV, 10 keV to 100 GeV, 100 keV to 10 GeV, 100 keV to 1 GeV, 100 keV to 200 MeV, 100 keV to 100 MeV, and 100 keV to 50 MeV. The initial kinetic energy of the free or bound electron to form a pseudoelectron by at least one mechanism of excitation such as the absorption of a high-energy photon and the production and absorption of a high-energy photon by Bremsstrahlung may be in at least one range of about 0 to 1 meV, 0 to 10 meV, 0 to 100 meV, 0 to 1 eV, 0 to 10 eV, 0 to 100 eV, 1 keV to 1 TeV, 10 keV to 100 GeV, 100 keV to 10 GeV, 100 keV to 1 GeV, 100 keV to 200 MeV, 100 keV to 100 MeV, and 100 keV to 50 MeV. The electric field of the capacitor to transduce the upward force on the pseudoelectron to lift of a desired object may be in at least one range of about 10 V/m to 10⁹ V/m, 100 V/m to 10⁸ V/m, 1 kV/m to 10⁸ V/m, 10⁴ V/m to 10⁷ V/m, and 10⁴ V/m to 2×10⁶ V/m. Based on the implicit understanding of the disclosure, energies or magnitudes of the energies are given.

### REFERENCES

1. F. C. Witteborn, W. M. and Fairbank, Physical Review Letters, Vol. 19, No. 18, (1967), pp. 1049-1052.
2. V. Fock, The Theory of Space, Time, and Gravitation, The MacMillan Company, (1964).
3. L. Z. Fang, and R. Ruffini, Basic Concepts in Relativistic Astrophysics, World Scientific, (1983).
4. G. R. Fowles, Analytical Mechanics, Third Edition, Holt, Rinehart, and Winston, N.Y., (1977), pp. 154-155.
5. C. Amsler, CERN Courier, “Antigravity matters at WAG 2013”, March 2014.
6. G. R. Fowles, Analytical Mechanics, Third Edition, Holt, Rinehart, and Winston, N.Y., (1977), pp. 140-164.
7. http://demonstrations.wolfram.com/SurfacesOfRevolutionWithConstantGaussianCurvatu re/.
8. M. Spivak, A Comprehensive Introduction to Differential Geometry, Vol. 3, 3rd ed., Houston: Publish or Perish, 1999, Chp 3.
9. N. V. Sidgwick, The Chemical Elements and Their Compounds, Volume I, Oxford, Clarendon Press, (1950), p.1
10. M. D. Lamb, Luminescence Spectroscopy, Academic Press, London, (1978), p. 68.
11. R. Mills, J. Lotoski, Y. Lu. “Mechanism of Soft X-ray Continuum Radiation from Low-Energy Pinch Discharges of Hydrogen and Ultra-low Field Ignition of Solid Fuels”, (2015), submitted.
12. R. L. Mills, Y. Lu, “Hydrino continuum transitions with cutoffs at 22.8 nm and 10.1 nm,” Int. J. Hydrogen Energy, 35 (2010), pp. 8446-8456, doi: 10.1016/j.ijhydene.2010.05.098.
13. R. L. Mills, Y. Lu, K. Akhtar, “Spectroscopic observation of helium-ion- and hydrogen-catalyzed hydrino transitions,” Cent. Eur. J. Phys., 8 (2010), pp. 318-339, doi: 10.2478/s11534-009-0106-9.
14. R. L. Mills, Y. Lu, “Time-resolved hydrino continuum transitions with cutoffs at 22.8 nm and 10.1 nm,” Eur. Phys. J. D, Vol. 64, (2011), pp. 65, DOI: 10.1140/epjd/e2011-20246-5.
15. R. L. Mills, R. Booker, Y. Lu, “Soft X-ray Continuum Radiation from Low-Energy Pinch Discharges of Hydrogen,” J. Plasma Physics, Vol. 79, (2013), pp 489-507; doi:10.1017/S0022377812001109.
16. A. Bykanov, “Validation of the observation of soft X-ray continuum radiation from low energy pinch discharges in the presence of molecular hydrogen,” http://www.blacklightpower.com/wp-content/uploads/pdf/GEN3_Harvard.pdf.
17. R. Mills J. Lotoski, “H₂O-based solid fuel power source based on the catalysis of H by HOH catalyst”, Int'l J. Hydrogen Energy, Vol. 40, (2015), pp. 25-37.
18. A. Beiser, Concepts of Modern Physics, Fourth Edition, McGraw-Hill Book Company, New York, (1978), pp. 153-155.
19. K. Akhtar, J. Scharer, R. L. Mills, “Substantial Doppler broadening of atomic-hydrogen lines in DC and capacitively coupled RF plasmas,” J. Phys. D, Applied Physics, Vol. 42, (2009), 42 135207 (2009) doi:10.1088/0022-3727/42/13/135207.
20. R. Mills, K. Akhtar, “Tests of features of field-acceleration models for the extraordinary selective H Balmer α broadening in certain hydrogen mixed plasmas,” Int. J. Hydrogen Energy, Vol. 34, (2009), pp. 6465-6477.
21. R. L. Mills, B. Dhandapani, K. Akhtar, “Excessive Balmer α line broadening of water-vapor capacitively-coupled RF discharge plasmas,” Int. J. Hydrogen Energy, Vol. 33, (2008), pp. 802-815.
22. R. Mills, P. Ray, B. Dhandapani, “Evidence of an energy transfer reaction between atomic hydrogen and argon II or helium II as the source of excessively hot H atoms in RF plasmas,” Journal of Plasma Physics, (2006), Vol. 72, Issue 4, pp. 469-484.
23. J. Phillips, C-K Chen, K. Akhtar, B. Dhandapani, R. Mills, “Evidence of catalytic production of hot hydrogen in RF generated hydrogen/argon plasmas,” International Journal of Hydrogen Energy, Vol. 32(14), (2007), 3010-3025.
24. R. L. Mills, P. C. Ray, R. M. Mayo, M. Nansteel, B. Dhandapani, J. Phillips, “Spectroscopic study of unique line broadening and inversion in low pressure microwave generated water plasmas,” J. Plasma Physics, Vol. 71, Part 6, (2005), pp. 877-888.
25. R. L. Mills, K. Akhtar, “Fast H in hydrogen mixed gas microwave plasmas when an atomic hydrogen supporting surface was present,” Int. J. Hydrogen Energy, 35 (2010), pp. 2546-2555, doi:10.1016/j.ijhydene.2009.12.148.
26. P. Weiss, Science News, Vol. 158, No. 14, September 30, (2000), p. 216.
27. P. Ball, Nature, http://helix.nature.com/nsu/000921/000921-1.html.
28. M. Chown, New Scientist, October 14, (2000), Vol. 168, Issue 2260, pp. 24, 33.
29. H. J. Maris, Journal of Low Temperature Physics, Vol. 120, (2000), p. 173.
30. Arnold J. Kelly, “Electrostatic Atomizing Device,” U.S. Pat. No. 4,581,675, Apr. 8, 1986.
31. F. A. Cotton, G. Wilkinson, Advanced Inorganic Chemistry A Comprehensive Text,

Interscience Publishers, New York, N.Y., (1962), pp. 193-194.
32. J. Lyons, H. Kippenhan, E. Wildforster, “Modeling soliton solutions to the sine-Gordon equation,” Dynamics at the Horsetooth, Volume 2, (2010), pp. 1-5.
33. R. K. Bullough, P. J. Caudrey (Eds.), Solitons, Springer-Verlag, Berlin, (1980).
34. W. McC. Siebert, Circuits, Signals, and Systems, The MIT Press, Cambridge, Mass., (1986), pp. 415-416.
35. G. O. Reynolds, J. B. DeVelis, G. B. Parrent, B. J. Thompson, The New Physical Optics Notebook, SPIE Optical Engineering Press, (1990).
36. G. R. Fowles, Analytical Mechanics, Third Edition, Holt, Rinehart, and Winston, N.Y., (1977), pp. 117-135.
37. G. R. Fowles, Analytical Mechanics, Third Edition, Holt, Rinehart, and Winston, N.Y., (1977), pp. 146-147.
38. D. P. Hardin, E. B. Saff, “Discretizing manifolds via minimum energy points,” Notices of the AMS, Vol. 51, No. 10, pp. 1186-1194.
39, H. Goldstein, Classical Mechanics, Cambridge, Mass.: Addison-Wesley, 1953.
40. J. W. Beams, “Ultrahigh-Speed Rotation”, pp. 135-147.
41. Feldman, D. W., et al., Nuclear Instruments and Methods in Physics Research, A259, (1987), pp. 26-30.
42. Nuclear Instruments and Methods in Physics Research, A272, (1,2), 1-616 (1988).
43. Nuclear Instruments and Methods in Physics Research, A259, (1,2), 1-316 (1987).
44. D. Horns, M. Myer, “Indications for a pair-production anomaly from the propagation of VHE gamma rays” http://arxiv.org/pdf/1201.4711v2.pdf.

1. An apparatus for providing lift from a gravitating body comprising:
a free electron;
means for applying energy to said free electron;
means for forming a pseudoelectron wherein a repulsive force away from said gravitating mass is created; and
means for applying a field to said pseudoelectron;
wherein a repulsive force is developed by said pseudoelectron in response to said applied field and is impressed on said means for applying the field in a direction away from said gravitating body.

2. The apparatus of claim 1, wherein the means of forming a pseudoelectron comprises an electron beam and a beam of high-energy photons, wherein the beams intersect such that the electrons form pseudoelectrons.

3. The means of claim 1, further comprising means for providing an electric field to provide a repulsive force against the pseudoelectron and to receive the repulsive force on said pseudoelectron by said gravitating mass.

4. The apparatus of claim 3, wherein the means to apply a field to provide a repulsive force against the pseudoelectron and receive the repulsive force on said pseudoelectron by said gravitating mass, comprises an electric field means for generating an electric field and which produces a force on the pseudoelectron which is in a direction opposite that of the force of the gravitating body on the pseudoelectron.

5. The apparatus of claim 1, further including
a circularly rotatable structure having a moment of inertia; and means for applying said repulsive force to circulating rotatable structure, wherein
the angular momentum vector of said circularly rotatable structure is parallel to the central vector of the gravitational force produced by said gravitating body.

6. The apparatus of claim 5, further comprising
means for changing the orientation of the angular momentum vector to accelerate the circularly rotatable structure along a trajectory substantially parallel to the surface of said gravitating mass.

7. (canceled)

8. An apparatus for providing a repulsion from a gravitating body, comprising:
a pseudoelectron which experiences a repulsive force in the presence of the gravitating body; and
means for applying a field to the pseudoelectron,
wherein a repulsive force is developed by the pseudoelectron in response to the applied field and is impressed on said means for applying the field in a direction away from the gravitating body.

9. The apparatus of claim 1, further comprising means for excluding external fields and cancel the electron magnetic moment.

10. A method of forming pseudoelectrons comprising the step of
providing at least one free electron;
providing an X-ray or gamma ray beam; and
providing the intersection of said at least one electron and X-ray or gamma ray beam such that the at least one electron forms at least one pseudoelectron.

11. The method of claim 10, wherein the step of providing at least one free electron comprises the step of excluding external fields and cancelling the electron magnetic moment.

12. The method of claim 11, further comprising the step of receiving the repulsive fifth force on a field source from the pseudoelectron in response to the force provided by the gravitating mass and the pseudoelectron comprising the step of,
providing an electric field which produces a force on the pseudoelectron which is in a direction opposite that of the force of the gravitating mass on the pseudoelectron.

13. The method of claim 12, further including the step of applying the received repulsive force to a structure movable in relation to said gravitating mass.

14. The method of claim 13, further including the step of rotating said structure around an axis providing an angular momentum vector of the circularly rotating structure parallel to the central vector of the gravitational force by the gravitating mass.

15. The method of claim 14, further including the step of changing the orientation of the angular momentum vector to accelerate the structure through a trajectory substantially parallel to the surface of the gravitating mass.
